(19) United States
(12) Patent Application Publication
(10) Pub. No.: US 2017/0025395 A1
(43) Pub. Date: Jan. 26, 2017

(54) Light Emitting Device

(71) Applicant: Everlight Electronics Co., Ltd., New Taipei City (TW)

(72) Inventors: Chien-Chih Chen, New Taipei City (TW); Ya Chin Tu, New Taipei City (TW); Chun Min Lin, New Taipei City (TW); Chieh-Yu Kang, New Taipei City (TW)

(21) Appl. No.: 15/216,839

(22) Filed: Jul. 22, 2016

(30) Foreign Application Priority Data
Jul. 22, 2015 (TW) 104123703
Aug. 25, 2015 (TW) 104127620

(51) Int. Cl. H01L 25/075; H01L 33/60; H01L 33/48; H01L 33/62; H01L 33/50

(52) U.S. Cl. CPC H01L 25/0753; H01L 33/62; H01L 33/505; H01L 33/483; H01L 33/60

(57) ABSTRACT

A light emitting device including a first work circuit and a second work circuit is provided. The first work circuit includes a first LED chip and a first bonding adhesive. The first LED chip and the first bonding adhesive are electrically connected in series. The second work circuit includes a second LED chip. When an operation current of the first work circuit and an operation current of the second work circuit are the same, the first work circuit has a first voltage V_{W1} and the second work circuit has a second voltage V_{W2}, wherein V_{W1}≈V_{W2}.

### CROSS REFERENCE TO RELATED PATENT APPLICATIONS

The present disclosure claims the priority benefit of Taiwan Patent Application No. 104123703, filed on Jul. 22, 2015, 2015, and Taiwan Patent Application No. 104127620, filed on Aug. 25, 2015, which are incorporated by reference in their entirety.

### TECHNICAL FIELD

The present disclosure relates to a light emitting device.

### BACKGROUND

With the evolution of lighting technology, light emitting diode chips (LED chips) have rapid been the dominative light sources used in modern light emitting devices. LED chips have many advantages such as lower power consumption, long service life, environmental friendliness, fast start, and compactness. In addition, the power capability of LED chips has been increasingly improved as the technology becomes more and more mature. Currently, LED chips have replaced traditional light sources in various light emitting devices and make light emitting devices more favorable to conservation of energy.

In practical applications, for color mixing or color changing, there are light emitting devices containing therein a plurality of LED chips. These LED chips emit light rays of different wavelengths, thereby providing color mixing or color changing as their buyers require. In particular, the light emitting devices of this kind usually at least include a first work circuit having a first LED chip and a second work circuit having a second LED chip. Since the first and second LED chips are made using different epitaxy methods or materials and therefore the first and second LED chips have different characteristics, when the same operation current is supplied to both of the first and second working circuits, different voltage drops happen in the first and second working circuits, making the entire light emitting device underperform. For addressing this issue, a resistance element has to be added and electrically connected to one of the working circuits. However, this additional resistance element means increased costs and waste heat.

### SUMMARY

For solving the foregoing problems, the present disclosure the first provides a scheme for modulating voltage drops in working circuits. Particularly, in this scheme, a light emitting device comprises a first work circuit and a second work circuit. The first work circuit comprises a first LED chip and a first bonding adhesive. The first LED chip is electrically connected in series with the first bonding adhesive. The second work circuit comprises a second LED chip. When an operation current I is used to operate the first work circuit and the second work circuit, the first work circuit has a first voltage drop V_{W1} and the second work circuit has a second voltage drop V_{W2}, wherein V_{W1}≈V_{W2}.

With the foregoing configuration, the disclosed light emitting device uses the first bonding adhesive that is connected in series with the first LED chip to make the first work circuit that comprises the first LED chip and the first bonding adhesive have a voltage drop similar or identical to that of the second work circuit that comprises the second LED chip. Thereby, the need of the additional resistance element as required in prior-art light emitting devices can be eliminated, and this in turn eliminates the problems about increased costs and waste heat.

The present disclosure as well as a preferred mode of use, further objectives and advantages thereof will be best understood by reference to the following detailed description of illustrative embodiments when read in conjunction with the accompanying drawings.

### BRIEF DESCRIPTION OF THE DRAWINGS

FIG. 1 is a schematic top view of a light emitting device according to one embodiment of the present disclosure.

FIG. 2 includes schematic cross-sectional views of the light emitting device taken along Lines A-A′, B-B′ and C-C′ of FIG. 2, respectively.

FIG. 3 is a schematic diagram of one equivalent circuit of the light emitting device of FIG. 2.

FIG. 4 is a schematic diagram of another equivalent circuit of the light emitting device of FIG. 2.

FIG. 5 is a schematic diagram of yet another equivalent circuit of the light emitting device of FIG. 2.

FIG. 6 is a schematic top view of a light emitting device according to another embodiment of the present disclosure.

FIG. 7 includes schematic cross-sectional views of the light emitting device Lines D-D′, E-E′ and F-F′ of FIG. 6, respectively.

FIG. 8 is a schematic diagram of one equivalent circuit of the light emitting device of FIG. 7.

FIG. 9A and FIG. 9B are schematic top and bottom views of a circuit substrate according to the embodiment.

FIG. 10 is a schematic side view of the circuit substrate as shown in FIG. 9A and FIG. 9B.

FIG. 11A and FIG. 11B are schematic top and bottom views of the circuit substrate as shown in FIG. 9A and FIG. 9B applied to a light emitting device.

FIG. 11C is a schematic circuit diagram of a lamp using the light emitting device of FIG. 11B.

FIG. 12 is a schematic side view of the light emitting device as shown in FIG. 11A through FIG. 11C.

FIG. 13A and FIG. 13B are schematic top and bottom views of a circuit substrate according to another embodiment of the present disclosure.

FIG. 14A and FIG. 14B are schematic top and bottom views of the circuit substrate as shown in FIG. 13A and FIG. 13B applied to a light emitting device.

FIG. 15A and FIG. 15B are schematic top and bottom views of a circuit substrate according to yet another embodiment of the present disclosure.

FIG. 16A and FIG. 16B are schematic top and bottom views of the circuit substrate as shown in FIG. 15A and FIG. 15B applied to a light emitting device.

FIG. 16C is a schematic circuit diagram of a lamp using the light emitting device of FIG. 16B.

### DETAILED DESCRIPTION

Reference is now made to the accompanying drawings for illustrating the scheme provided by the present disclosure for modulating voltage drops.

### <First Aspect>

In the present aspect, a light emitting device includes a first work circuit and a second work circuit. The first work circuit comprises a first LED chip and a first bonding adhesive. The first LED chip and the first bonding adhesive are electrically connected in series. The second work circuit comprises a second LED chip. When an operation current I is used to operate both of the first and second work circuits, the first work circuit has first voltage drop V_{W1}, and a second work circuit has a second voltage drop V_{W2}, wherein V_{W1}≈V_{W2}. The specific implement is detailed below.

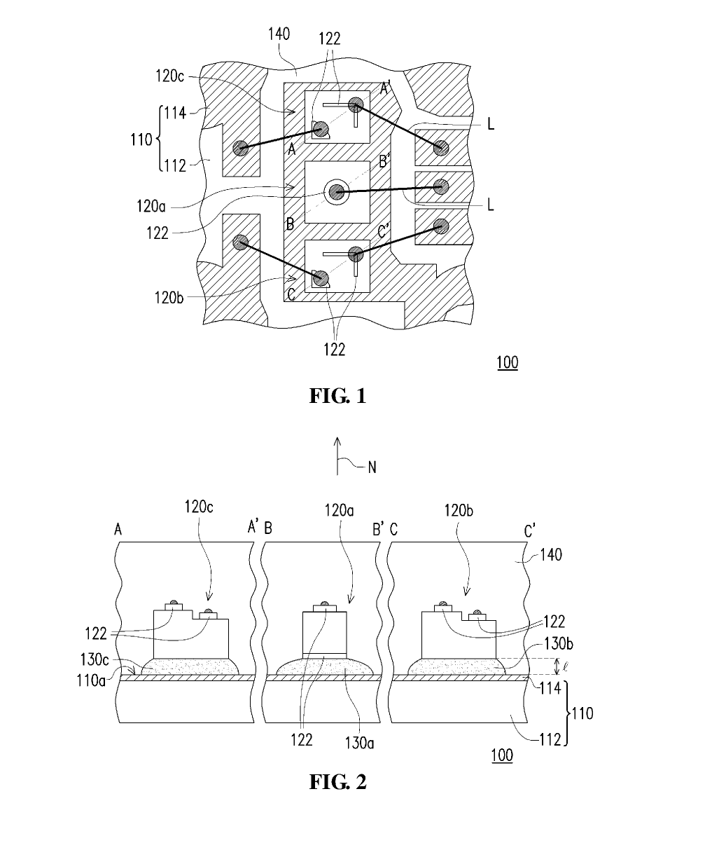

FIG. 1 is a schematic top view of a light emitting device according to one embodiment of the present disclosure. FIG. 2 includes schematic cross-sectional views of the light emitting device taken along Lines A-A′, B-B′ and C-C′ of FIG. 2, respectively. Referring to FIG. 1 and FIG. 2, in the present embodiment, the light emitting device 100 may be configured on a circuit substrate 110. The circuit substrate 110 comprises an insulating base 112 and is configured on a circuit layer 114 of the insulating base 112. The light emitting device 100 and the circuit layer 114 are electrically connected. Through the circuit layer 114, the light emitting device 100 is electrically connected to an external power source (not shown), thereby emitting light. The light emitting device 100 may optionally be coated with an encapsulation compound 140, but the present disclosure is not limited thereto. In addition, the encapsulation compound 140 may comprise fluorescent powder that covers the first LED chip and/or the second LED chip (and also covers the third chip if the latter is present). Moreover, different LED chips may be covered by different kinds of fluorescent powder, so as to obtain different light colors as desired. Selection of the fluorescent powder will be detailed below. In addition, where the fluorescent powder is applied, there may be a retaining wall arranged between the chips, such as between the first LED chip and the second LED chip, so as to prevent illumination of one chip from exciting fluorescent powder on the adjacent chips. Preferably, the retaining wall comprises a reflective material so as to enhance light extraction efficiency. Selection of the reflective material will be detailed below.

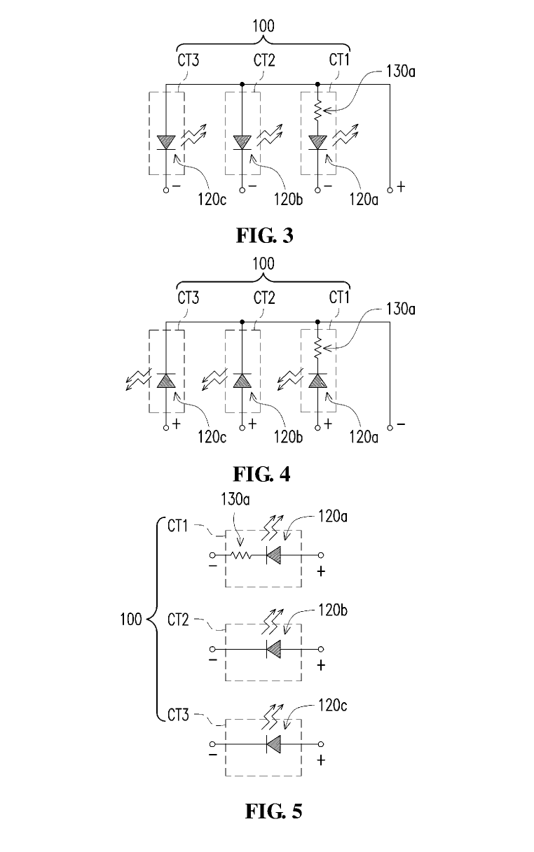

FIG. 3 is a schematic diagram of one equivalent circuit of the light emitting device of FIG. 2. Referring to FIG. 2 and FIG. 3, for example, in the present embodiment, the light emitting device 100 may have the first LED chip 120a, the second LED chip 120b and third LED chip 120c electrically connected to an external power source (not shown) in a common-anode manner, thereby emitting light. However, the present disclosure is not limited thereto. FIG. 4 is a schematic diagram of another equivalent circuit of the light emitting device of FIG. 2. Referring to FIG. 4, in another embodiment, the first LED chip 120a, the second LED chip 120b and the third LED chip 120c may be electrically connected to an external power source in a common-cathode manner, thereby emitting light. FIG. 5 is a schematic diagram of yet another equivalent circuit of the light emitting device of FIG. 2. Referring to FIG. 5, in the present embodiment of the present disclosure, the first LED chip 120a, the second LED chip 120b, and the third LED chip 120c may be electrically connected to an external power source in an independent manner, thereby emitting light. In short, the present disclosure puts no limitation to how the light emitting device 100 is electrically connected to an external power source, and the connection may be decided according to practical needs.

Referring to FIG. 2, the light emitting device 100 at least includes the first LED chip 120a, the second LED chip 120b, the first bonding adhesive 130a and the second bonding adhesive 130b. The first LED chip 120a and the second LED chip 120b are fixed to the circuit substrate 110 by means of the first bonding adhesive 130a and the second bonding adhesive 130b, respectively. In the present embodiment, the light emitting device 100 may further include a third LED chip 120c and a third bonding adhesive 130c. The third LED chip 120c is fixed to the circuit substrate 110 by means of the third bonding adhesive 130c. In the present embodiment, the first LED chip 120a, the second LED chip 120b, and the third LED chip 120c may be a red-light chip, a green-light chip, and a blue-light chip, respectively, but the present disclosure is not limited thereto. In other embodiments, the first LED chip 120a, the second LED chip 120b, and the third LED chip 120c may emit light of colors of any combination.

Referring to FIG. 2 and FIG. 3, the first LED chip 120a and the first bonding adhesive 130a are electrically connected in series. For example, in the present embodiment, as shown in FIG. 2, the first LED chip 120a may have its two electrodes 122 located on upper and lower surfaces of the first LED chip 120a, respectively. Stated differently, the first LED chip 120a may optionally be a vertical chip. The electrode 122 located on the lower surface of the first LED chip 120a may have electric contact with the conductive first bonding adhesive 130a, so that the first LED chip 120a and the first bonding adhesive 130a are connected in series. On the other hand, as shown in FIG. 1 and FIG. 2, the electrode 122 located on the upper surface of the first LED chip 120a may be electrically connected to the corresponding part of the circuit layer 114 by means of a lead L. Referring to FIG. 1 through FIG. 3, the first LED chip 120a, the first bonding adhesive 130a and the part of the circuit layer 114 to which the first LED chip 120a is electrically connected to may form a first work circuit CT1. Since the circuit layer 114 and the lead L are well conductive and have extremely small resistance, in the equivalent circuit diagram of FIG. 3, the impact of the resistance of the circuit layer 114 and the resistance of the lead L on the first work circuit CT1 may be ignored.

Referring to FIG. 1 and FIG. 2, in the present embodiment, the second LED chip 120b may have its two electrodes 122 both located on the upper surface of the second LED chip 120b. Stated differently, the second LED chip 120b may optionally be a horizontal chip. As shown in FIG. 1, the second LED chip 120b has its two electrodes 122 electrically connected to the corresponding circuit layer 114 by means of two leads L, respectively. On the other hand, as shown in FIG. 2, the second LED chip 120b has its lower surface connected to the second bonding adhesive 130b, and the two electrodes 122 of the second LED chip 120b are separated from the second bonding adhesive 130b. Therefore, the second LED chip 120b and the second bonding adhesive 130b are electrically isolated from each other. Referring to FIG. 1 through FIG. 3, the second LED chip 120b and the part of the circuit layer 114 that is electrically connected to the second LED chip 120b may form a second work circuit CT2. Since the circuit layer 114 and the lead L are well conductive and have extremely small resistance, in the equivalent circuit diagram of FIG. 3, the impact of the resistance of the circuit layer 114 and the resistance of the lead L on the second work circuit CT2 may be ignored. In addition, in the present embodiment, since the second LED chip 120b and the second bonding adhesive 130b are electrically isolated from each other, the impact of the second bonding adhesive 130b on the second work circuit CT2 is also ignored.

Referring to FIG. 1 and FIG. 2, similar to the second LED chip 120b, in the present embodiment, the third LED chip 120c also has its both electrodes 122 located on the upper surface of the third LED chip 120c. Stated differently, the third LED chip 120c may be optionally a horizontal chip. As shown in FIG. 1, the third LED chip 120c has its two electrodes 122 electrically connected to the corresponding circuit layer 114 by means of two leads L, respectively. On the other hand, as shown in FIG. 2, the third LED chip 120c has its lower surface connected to the third bonding adhesive 130c, and the two electrodes 122 of the third LED chip 120c are separated from the third bonding adhesive 130c, so the third LED chip 120c and the third bonding adhesive 130c are electrically isolated from each other. Referring to FIG. 1 through FIG. 3, the third LED chip 120c and the part of the circuit layer 114 to which the third LED chip 120c is electrically connected may form a third work circuit CT3. Since the circuit layer 114 and the lead L are well conductive and have extremely small resistance, in the equivalent circuit diagram of FIG. 3, the impact of the resistance of the circuit layer 114 and the resistance of the lead L on the third work circuit CT3 may be ignored. In addition, in the present embodiment, since the third LED chip 120c and the third bonding adhesive 130c are electrically isolated from each other, the impact of the third bonding adhesive 130c on the third work circuit CT3 is ignored.

It is to be noted that, as shown in FIG. 3, by using the first bonding adhesive 130a to coordinate and modulate resistance, the first work circuit CT1, the second work circuit CT2 and the third work circuit CT3 can have the same voltage drop. As such, when used, the light emitting device 100 does not need any additional resistance element as required by the conventional devices, thereby eliminating the problems about increased costs and waste heat.

Referring to FIG. 3, in particular, one focal point of the present disclosure is that, when the first forward voltage V1 of the first LED chip 120a is different from the second forward voltage V2 of the second LED chip 120b or the third forward voltage V3 of the third LED chip 120c, and particularly when the diversity ratio between the first forward voltage V1 and the second forward voltage V2 ((V2−V1)/V2) is greater than 15%, preferably greater than about 30%, it is possible to use the resistance of the first bonding adhesive 130a to modulate the voltage drop V_{W1} of the first work circuit CT1, thereby making V_{W1} approximately close to or equal to V_{W2} or V_{W3}. Stated broadly, when an operation current I is used to operate the first work circuit CT1, the first LED chip 120a has the first forward voltage V1, and the voltage drop at the first bonding adhesive 130a is (I×R₁), where R₁ is the resistance of the first bonding adhesive 130a. At this time, the first voltage drop V_{W1} of the first work circuit CT1 is [V₁+(I×R₁)]. When the same current I is used to operate the second work circuit CT2, the second LED chip 120b has the second forward voltage V2, and the second voltage drop V_{W2} of the second work circuit CT2 is V2. When the same current I is used to operate the third work circuit CT3, the third LED chip 120c has the third forward voltage V3, and the third voltage drop V_{W3} of the third work circuit CT3 is V3. By properly designing the resistance R₁ of the first bonding adhesive 130a, the following Equation (1) can be satisfied: V₁(I×R₁)≈V₂≈V₃. That is, when the resistance R₁ of the first bonding adhesive 130a is properly designed, the first voltage drop V_{W1} of the first work circuit CT1 (i.e. [V₁+(I×R₁)]) is approximately equal to the second voltage drop V_{W2} of the second work circuit CT2 (i.e. V2) and the third voltage drop V_{W3} of the third work circuit CT3 (i.e. V3).

Taking specific quantitative values for example, in the present disclosure, the ratio between V_{W1} and V_{W2} (or V_{W3}) may be about 0.785 to about 0.95. For example, when the operation current I for the first work circuit CT1, the second work circuit CT2 and the third work circuit CT3 is 10 mA, the first LED chip 120a has the first forward voltage V1, the second LED chip 120b has the second forward voltage V2, and the third LED chip 120c has the third forward voltage V3, wherein the first forward voltage V1 is about 1.9 to about 2.0 Volt, the second forward voltage V2 is about 3.0 to about 3.5 Volt, and the third forward voltage V3 is about 3.0 to about 3.5 Volt. By applying the quantitative values of the operation current I, the first forward voltage V1, the second forward voltage V2, the third forward voltage V3 to Equation (1), the required resistance R₁ of the first bonding adhesive 130a can be determined.

In the present disclosure, the first bonding adhesive 130a is a resin composition, which contains conductive ceramic particles. In particular, the resin may be epoxy resin or silicone resin. In the embodiments provided herein for illustrating the present disclosure, epoxy resin is taken for example. The conductive ceramic particles may be any materials that have electric conductivity under given working voltage and current, such as indium-tin oxide particles, carbon particles and any combination thereof. As compared to metal particles, conductive ceramic particles provide higher electric impedance, and are more suitable for modulating the resistance R₁ of the first bonding adhesive 130a. Preferably, in the present disclosure, electrically conductive ceramic particles provide electric conductivity. However, without going against the spirit of the present disclosure, a trace amount of metal particles may be added into the first bonding adhesive, thereby obtaining appropriate resistance R₁. In the present embodiment, carbon particles having impedance of 3.5×10⁻⁵ and indium-tin oxide having impedance of 3.5×10⁻⁵ are used for example, without any metal particles. Blending concentration may vary with desired electric conductivity and adhesion or other properties of the resin composition. Based on weight percentage of the resin composition, the electrically conductive ceramic particles have a concentration preferably about 20% to about 80%. A concentration lower than 20% is too low to generate even electric conductivity, while a concentration higher than 80% may adversely affect adhesion or other properties of the bonding adhesive, in turn significantly reducing its operational stability and reliability of end products. However, the present disclosure is not limited to the aforementioned resin composition and material and blending concentration of the electrically conductive ceramic particles. With the disclosure of the present disclosure, people skilled in the art may adjust the material used and concentration to achieve the objectives of the present disclosure readily.

In the present disclosure, the resistance R₁ of the first bonding adhesive 130a may be controlled by designing the thickness l and area A of the first bonding adhesive on the surface 110a of the circuit substrate 110. With consideration to the chip area and to the thickness of the final device, the first bonding adhesive preferably has its thickness l ranging from about 2 μm to about 15 μm, and the area A preferably ranges from about 0.015 mm² to about 0.15 mm². However, the present disclosure is not limited to the recited thickness and area. With the disclosure of the present disclosure, people skilled in the art may adjust the dimensions and achieve the objectives of the present disclosure readily.

In Table I given below, bonding adhesive materials having various compositions are provided. In some experiments, the various bonding adhesive materials listed in Table I were used to make bonding adhesive having the area A and thickness l as described previously (area: 0.04 mm²; thickness: 8 μm). Table I also reflects the variations of the first voltage drop V_{W1} of the first work circuit CT1 when the first bonding adhesive 130a of FIG. 2 was realized using the listed materials as actually measured.

TABLE I

| | | | | | Indium-Tin | |
|---|---|---|---|---|---|---|
| Particle Material | | Silver | Carbon | | Oxide | Silicone |
| Particle Impedance (Ω · m) | | 1 × 10⁻⁸ | 3.5 × 10⁻⁵ | | 1 × 10⁻⁴ | 6.4 × 10² |
| Bonding | Particle Weight | 70% | 70% | 50% | 70% | 70% |
| adhesive | Percentage | | | | | |
| Material | Epoxy Resin | 28%~30% | 28%~30% | 48%~50% | 28%~30% | 28%~30% |
| | Weight Percentage | | | | | |

| | | | | | |
|---|---|---|---|---|---|
| Actually Measured First | 2.0 V | 2.15 V | 2.75 V | 2.87 V | 4.02 V |
| Voltage Drop V_{W1} | | | | | |

The data provided in Table I may be used by a designer to determine the suitable material of the first bonding adhesive 130a. For example, in the present embodiment, when the operation current I operates the first work circuit CT1, the second work circuit CT2 and the third work circuit CT3 is 10 mA, the second voltage drop V_{W2} is about 3.0 to about 3.5V and the third voltage drop V_{W3} is about 3.0 to about 3.5V. A designer may want to use the first bonding adhesive 130a having appropriate resistance to make the first voltage drop V_{W1} close to the second voltage drop V_{W2} and the third voltage drop V_{W3} (about 3.0 to about 3.5V). As shown in Table I, when the resin composition used to make the first bonding adhesive 130a of FIG. 2 comprises about 48%˜about 50% of epoxy resin and has 50% of carbon particles blended in the epoxy resin, the actually measured first voltage drop V_{W1} was 2.75V, close to the second voltage drop V_{W2} and the third voltage drop V_{W3} (about 3.0 to about 3.5V). That is to say, a resin composition comprising about 48%˜about 50% of epoxy resin and about 50% of carbon particles may be used to make the first bonding adhesive 130a. As shown in Table I, when the resin composition used to make the first bonding adhesive 130a of FIG. 2 comprises about 28%˜about 30% of epoxy resin and has about 70% of indium-tin oxide particles blended into the epoxy resin, the actually measured first voltage drop V_{W1} was 2.87V, close to the second voltage drop V_{W2} and the third voltage drop V_{W3} (about 3.0 to about 3.5V). That is to say, a resin composition comprising about 28%˜about 30% of epoxy resin and about 70% of indium-tin oxide particles may be used to make the first bonding adhesive 130a. On the other hand, as shown in Table I, when the resin composition used to make the first bonding adhesive 130a of FIG. 2 comprises about 28%˜about 30% of epoxy resin and has about 70% of carbon particles blended into the epoxy resin, the actually measured first voltage drop V_{W1} was 2.15V, significantly different from the second voltage drop V_{W2} and the third voltage drop V_{W3} (about 3.0 to about 3.5V). The resin composition is thus relatively not suitable for making the first bonding adhesive 130a. As shown in Table I, when the resin composition used to make the first bonding adhesive 130a of FIG. 2 comprises about 28%˜about 30% of epoxy resin and has about 70% of silicone particles blended into the epoxy resin, the actually measured first voltage drop V_{W1} was 4.02V, significantly different from the second voltage drop V_{W2} and the third voltage drop V_{W3} (about 3.0 to about 3.5V). The resin composition is thus relatively not suitable for making the first bonding adhesive 130a.

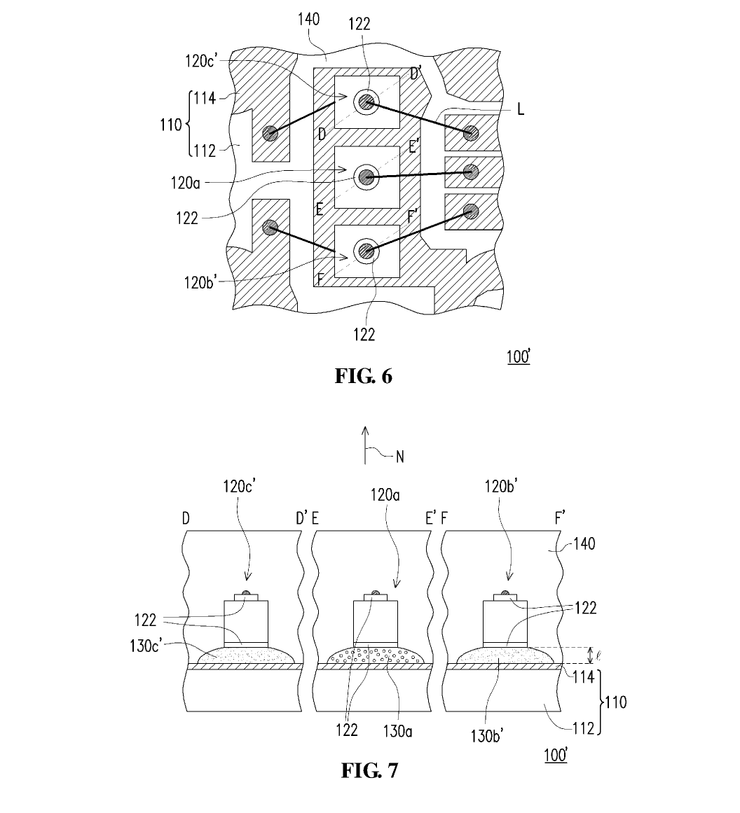

Referring back to FIG. 2 and FIG. 3, in the present embodiment, the second bonding adhesive 130b and the third bonding adhesive 130c are electrically isolated from the second LED chip 120b and the third LED chip 120c they correspond, respectively. The resistance of the second bonding adhesive 130b and the resistance of the third bonding adhesive 130c have no effects on the second voltage drop V_{W2} of the second work circuit CT2 and the third voltage drop V_{W3} of the third work circuit CT3. Therefore, the second bonding adhesive 130b and the third bonding adhesive 130c may be made of materials identical to or different from that of the first bonding adhesive 130a. Preferably, in the present embodiment, the first bonding adhesive 130a, the second bonding adhesive 130b and the third bonding adhesive 130c may be made of the same material so as to be implemented in the same process, thereby saving manufacturing time. The process may be dispensing process, screen printing process, B-stage prepreg laminating process or other appropriate manufacturing process. Preferably, screen printing process or B-stage prepreg is implemented to control application of the first bonding adhesive in terms of thickness and area. However, the present disclosure is not limited thereto. In other embodiments, the first bonding adhesive 130a, the second bonding adhesive 130b and the third bonding adhesive 130c may be made of different materials and are not necessarily formed in the same process. This will be detailed below referring to a second aspect as depicted in FIG. 6 and FIG. 7.

As described previously, after die bonding and wiring, packaging may be performed to protect chips and wire solder. In detail, packaging is performed by using the encapsulation compound 140 to cover chips, leads and the circuit substrate. The encapsulation compound may contain fluorescent powder to further change the color of the emitted light. Preferably, one or more kinds of fluorescent powder selected from below are used: Sr₅(PO₄)₃Cl:Eu²⁺, (Sr,Ba)MgAl₁₀O₁₇:Eu²⁺, (Sr,Ba)₃MgSi₂O₈:Eu²⁺, SrAl₂O₄:Eu²⁺, SrBaSiO₄:Eu^{2+,} CdS:In, CaS:Ce³⁺, Y₃(Al,Gd)₅O₁₂:Ce²⁺, Ca₃Sc₂Si₃O₁₂:Ce³⁺, SrSiON:Eu²⁺, ZnS:Al³⁺,Cu⁺, CaS:Sn²⁺, CaS:Sn²⁺,F, CaSO₄:Ce³⁺,Mn²⁺, LiAlO₂:Mn²⁺, BaMgAl₁₀O₁₇:Eu²⁺,Mn²⁺, ZnS:Cu⁺,Cl⁻, Ca₃WO₆:U, Ca₃SiO₄C₁₂:Eu²⁺, SrₓBa_{y}Cl_{z}Al₂O_{4-z/2}:Ce³⁺,Mn²⁺ (X:0.2, Y:0.7, Z:1.1), Ba₂MgSi₂O₇:Eu^{2+,} Ba₂SiO₄:Eu²⁺, Ba₂Li₂Si₂O₇:Eu²⁺, ZnO:S, ZnO:Zn, Ca₂Ba₃(PO₄)₃Cl:Eu²⁺, BaAl₂O₄:Eu²⁺, SrGa₂S₄:Eu²⁺, ZnS:Eu²⁺, Ba₅(PO₄)₃Cl:U, Sr₃WO₆:U, CaGa₂S₄:Eu²⁺, SrSO₄:Eu²⁺,Mn²⁺, ZnS:P, ZnS:P³⁻,Cl⁻, ZnS:Mn²⁺, CaS:Yb²⁺,Cl, Gd₃Ga₄O₁₂:Cr³⁺, CaGa₂S₄:Mn²⁺, Na(Mg,Mn)₂LiSi₄O₁₀F₂:Mn, ZnS:Sn²⁺, Y₃Al₅O₁₂:Cr³⁺, SrB₈O₁₃:Sm²⁺, MgSr₃Si₂O₈:Eu²⁺,Mn²⁺, α-SrO.3B₂O₃:Sm²⁺, ZnS—CdS, ZnSe:Cu⁺,Cl, ZnGa₂S₄:Mn²⁺, ZnO:Bi³⁺, BaS:Au,K, ZnS:Pb²⁺, ZnS:Sn²⁺,Li⁺, ZnS:Pb,Cu, CaTiO₃:Pr³⁺, CaTiO₃:Eu³⁺, Y₂O₃:Eu³⁺, (Y,Gd)₂O₃:Eu³⁺, CaS:Pb²⁺,Mn²⁺, YPO₄:Eu³⁺, Ca₂MgSi₂O₇:Eu²⁺,Mn²⁺, Y(P,V)O₄:Eu³⁺, Y₂O₂S:Eu³⁺, SrAl₄O₇:Eu³⁺, CaYAlO₄:Eu³⁺, LaO₂S:Eu³⁺, LiW₂O₈:Eu³⁺,Sm³⁺, (Sr,Ca,Ba,Mg)₁₀(PO₄)₆Cl₂:Eu²⁺,Mn²⁺, Ba₃MgSi₂O₈: Eu²⁺,Mn²⁺, ZnS:Mn²⁺,Te²⁺, Mg₂TiO₄:Mn⁴⁺, K₂SiF₆:Mn⁴⁺, SrS:Eu²⁺, Na_{1.23}K_{0.42}Eu_{0.12}TiSi₄O₁₁, Na_{1.23}K_{0.42}Eu_{0.12}TiSi₅O₁₃:Eu³⁺, CdS:In,Te, CaAlSiN₃:Eu²⁺, CaSiN₃:Eu²⁺, (Ca,Sr)₂Si₅N₈:Eu²⁺ and Eu₂W₂O₇.

The above description explains the spirit and principle of the scheme for modulating voltage drops by referring to the first aspect of the present disclosure, and more aspects will be further provided below.

### <Second Aspect>

FIG. 6 is a schematic top view of a light emitting device according to another embodiment of the present disclosure. FIG. 7 includes schematic cross-sectional views of the light emitting device Lines D-D′, E-E′ and F-F′ of FIG. 6, respectively. The light emitting device 100′ of FIG. 6 and FIG. 7 is similar to the light emitting device 100 shown in FIG. 1 and FIG. 2, and like elements are identified by identical or corresponding numbers in the figures. What differentiates the light emitting device 100′ of FIG. 6 and FIG. 7 from the light emitting device 100 of FIG. 1 and FIG. 2 is that: the second LED chip 120b′ and the third LED chip 120c′ of FIG. 6 and FIG. 7 are of a from different from that of the second LED chip 120b and the third LED chip 120c of FIG. 1 and FIG. 2. Further description will be focused on the difference, and since the similarities of the both will be understood by referring to FIG. 6 and FIG. 7 together with the foregoing explanation, no repetition is made herein.

Referring to FIG. 6 and FIG. 7, the light emitting device 100′ at least comprises a first LED chip 120a, a second LED chip 120b′, a first bonding adhesive 130a and a second bonding adhesive 130b′. The first LED chip 120a and the second LED chip 120b′ are secured to the circuit substrate 110 by means of the first bonding adhesive 130a and the second bonding adhesive 130b′, respectively. In the present embodiment, the light emitting device 100′ may further comprise a third LED chip 120c′ and a third bonding adhesive 130c′. The third LED chip 120c′ is secured to the circuit substrate 110 by means of the third bonding adhesive 130c′.

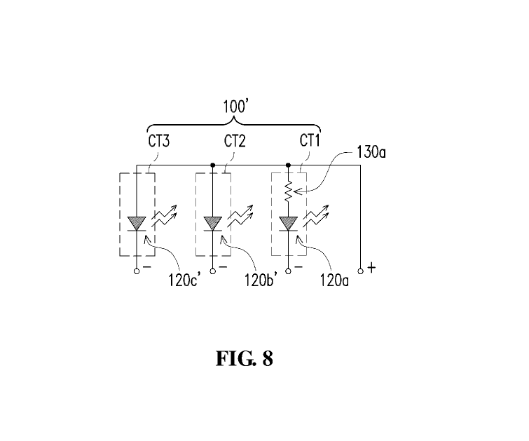

FIG. 8 is a schematic diagram of one equivalent circuit of the light emitting device of FIG. 7. Referring to FIG. 7 and FIG. 8, the first LED chip 120a and the first bonding adhesive 130a are connected in series. For example, in the present embodiment, the first LED chip 120a may be a vertical chip. An electrode 122 located on the lower surface of the first LED chip 120a in electric contact with the first bonding adhesive 130a, so that the first LED chip 120a and the first bonding adhesive 130a are connected in series. The first work circuit CT1 comprises a first LED chip 120a, a first bonding adhesive 130a that is connected in series with the first LED chip 120a, and a part of the circuit layer 114 that is electrically connected to the first LED chip 120a. In the present disclosure, when the second LED chip 120b′ and the third LED chip 120c′ are adopted, the corresponding second bonding adhesive 130b′ and third bonding adhesive 130c′ are made of the convention, highly conductive bonding adhesive, such as silver paste. In the equivalent circuit diagram of FIG. 8, the second work circuit CT2 and the third work circuit CT3 may ignore the contribution of the second bonding adhesive 130b′ and the third bonding adhesive 130c′. In addition, the circuit layer 114 is well conductive and has extremely small resistance, and thus, in the equivalent circuit diagram of FIG. 8, the first work circuit CT1 may ignore the contribution of the circuit layer 114.

Comparing FIG. 2 and FIG. 7, the light emitting device 100′ is different from the light emitting device 100 for the second LED chip 120b′ and the third LED chip 120c′ may be vertical chips. Referring to FIG. 7, the second LED chip 120b′ and the second bonding adhesive 130b′ are connected in series. For example, in the present embodiment, an electrode 122 located on the lower surface of the second LED chip 120b′ is in electric contact with the second bonding adhesive 130b′, so that the second LED chip 120b′ and the second bonding adhesive 130b′ are connected in series. Referring to FIG. 7 and FIG. 8, the second work circuit CT2 comprises a second LED chip 120b′, a second bonding adhesive 130b′ that is connected in series with the second LED chip 120b′, and a part of the circuit layer 114 that is electrically connected to the second LED chip 120b′. The second bonding adhesive 130b′ may be a resin composition containing metal particles, such as a mixture of silver particles and epoxy resin (i.e. the so-called silver paste), but the present disclosure is not limited thereto. As described previously, the circuit layer 114 and the second bonding adhesive 130b′ are both well conductive and have extremely small resistance, so, in the equivalent circuit diagram of FIG. 8, the second work circuit CT2 may ignore the contribution of the circuit layer 114 and the second bonding adhesive 130b′.

Similarly, referring to FIG. 7, the third LED chip 120c′ and the third bonding adhesive 130c′ are connected in series. For example, in the present embodiment, an electrode 122 located on the lower surface of the third LED chip 120c′ is electrically connected to the third bonding adhesive 130c′, so that the third LED chip 120c′ and the third bonding adhesive 130c′ are connected in series. Referring to FIG. 7 and FIG. 8, the third work circuit CT3 comprises a third LED chip 120c′, a third bonding adhesive 130c′ that is connected in series with the third LED chip 120c′, and a part of the circuit layer 114 that is electrically connected to the third LED chip 120c′. The third bonding adhesive 130c′ may be a resin composition containing metal particles, such as a mixture of silver particles and epoxy resin, but the present disclosure is not limited thereto. As described previously, the circuit layer 114 and the third bonding adhesive 130c′ are both well conductive and have extremely small resistance, so, in the equivalent circuit diagram of FIG. 8, the third work circuit CT3 may ignore the contribution of the circuit layer 114 and the third bonding adhesive 130c′.

In the present embodiment, the resistance of the first bonding adhesive 130a is much greater than the resistance of the second bonding adhesive 130b′, and the resistance of the first bonding adhesive 130a is much greater than the resistance of the third bonding adhesive 130c′. In other words, the first bonding adhesive 130a is of a material different that/those of the second bonding adhesive 130b′ and the third bonding adhesive 130c′. The second bonding adhesive 130b′ and the third bonding adhesive 130c′ may be made of identical or different materials. The layers of bonding adhesive made of different materials may be applied on the circuit substrate 110 one after another. For example, when the second bonding adhesive 130b′ and the third bonding adhesive 130c′ are made of an identical material, and the material of the first bonding adhesive 130a is different from the material of the second bonding adhesive 130b′, the second bonding adhesive 130b′ and the third bonding adhesive 130c′ may be formed in one process, and the first bonding adhesive 130a may be formed in another process. The process may be a dispensing process, a screen printing process, a B-stage prepreg laminating process or other appropriate processes.

Referring to FIG. 8, similar to the light emitting device 100, the light emitting device 100′ uses the first bonding adhesive 130a connected in series with the first LED chip 120a to make the first voltage drop V_{W1} of the first work circuit CT1 identical to the second voltage drop V_{W2} of the second work circuit CT2 and the third voltage drop V_{W3} of the third work circuit CT3. As such, when used, the light emitting device 100′ does not need any additional resistance element as required by the conventional devices. For obtaining the desired resistance of the first bonding adhesive 130a, selection of the composition may be made with reference to the foregoing description, and no repetition is made herein. In addition, as shown in FIG. 8, in the present embodiment, the first LED chip 120a, the second LED chip 120b′, and the third LED chip 120c′ of the light emitting device 100′ are electrically connected in a common-anode manner to an external power source (not shown), thereby emitting light. However, the first LED chip 120a, the second LED chip 120b′, and the third LED chip 120c′ of the light emitting device 100′ may alternatively be electrically connected to the electrically connected in a common-cathode manner or independently, thereby emitting light. In short, the present disclosure puts no limitation on how the light emitting device 100′ and the external power source are electrically connected, and the connection may be decided according to practical needs.

To sum up, the disclosed light emitting device uses the first bonding adhesive connected in series with the first LED chip to make the first work circuit that comprises the first LED chip and the first bonding adhesive have a voltage drop close or identical to that of the second work circuit that comprises the second LED chip. As such, when used, the light emitting device does not need any additional resistance element as required by the conventional devices, thereby eliminating the problems about increased costs and waste heat.

While the above description teaches using a single vertical chip and the disclosed bonding adhesive to modulate the voltage drop of the work circuit, in practical applications where a plurality of chips are connected in series/parallel, the disclosed scheme is also useful to modulate individual vertical chips and the total voltage drop of the bonding adhesives, so as to make the voltage drops of all the horizontal chips identical, thereby achieving a work circuit having identical voltage drops easily. More details will be given below for explaining the disclosed light emitting device of serial connection and its circuit configuration.

Stated broadly, in the following aspect, the substrate of the light emitting device has a serial-connection design. In addition, the light emitting device has a specially designed circuit substrate, and is suitable to provide plural sets of electric loops with integrated configuration of polarity, so as to simplify circuit configuration of a circuit mainboard at the users' side. This eliminates the needs of jumper wires and multilayer circuit structure, which mean significantly increased costs and reduced reliability of the resulting lamp. In detail, in the present embodiment, the light emitting device comprises a circuit substrate and one or more LED chips, wherein the circuit substrate comprises an insulating base and a first pattern. The insulating base has back to back a first surface and a second surface. The first pattern is configured on the first surface. The first pattern comprises a first pad pair, a second pad pair, a third pad pair, a fourth pad pair, and a communicating pad. The first pad pair comprises a first die-bonding pad and a first matching pad. The second pad pair comprises a second die-bonding pad and a second matching pad. The third pad pair comprises a third die-bonding pad and a third matching pad. The fourth pad pair comprises a fourth die-bonding pad and a fourth matching pad. The communicating pad is electrically connected to the first matching pad and the third die-bonding pad. The LED chips are each configured on one of the first die-bonding pad, the second die-bonding pad, the third die-bonding pad and the fourth die-bonding pad. Thereby, the first pad pair, the third pad pair and the communicating pad constitute a set of electric loop, while the second pad pair and the fourth pad pair each constitute a set of electric loop. A third, a fourth and a fifth aspects will be described below to illustrate the design schemes of the substrate and light emitting devices made therefrom.

### <Third Aspect>

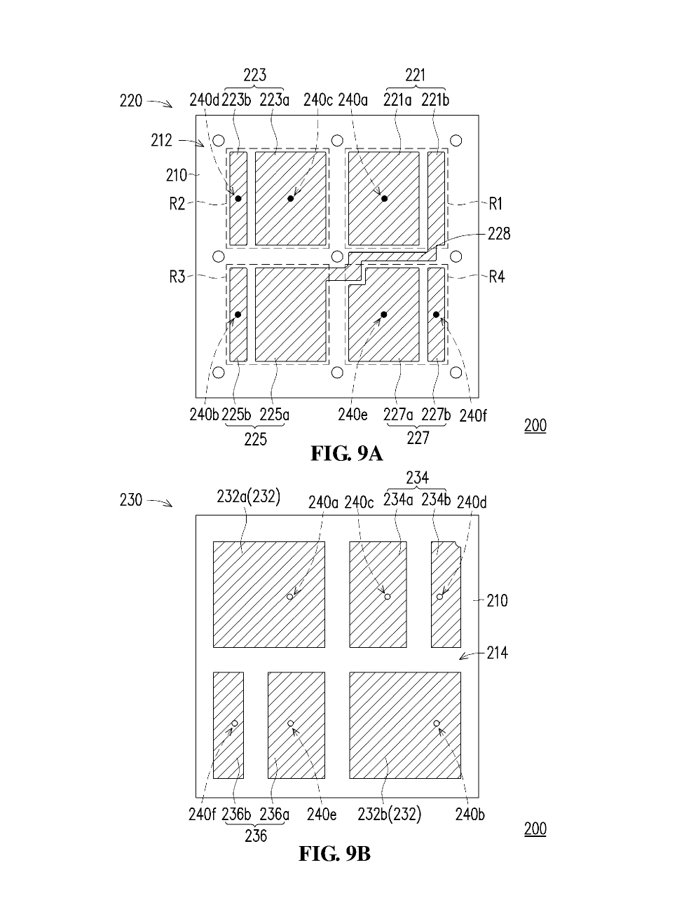

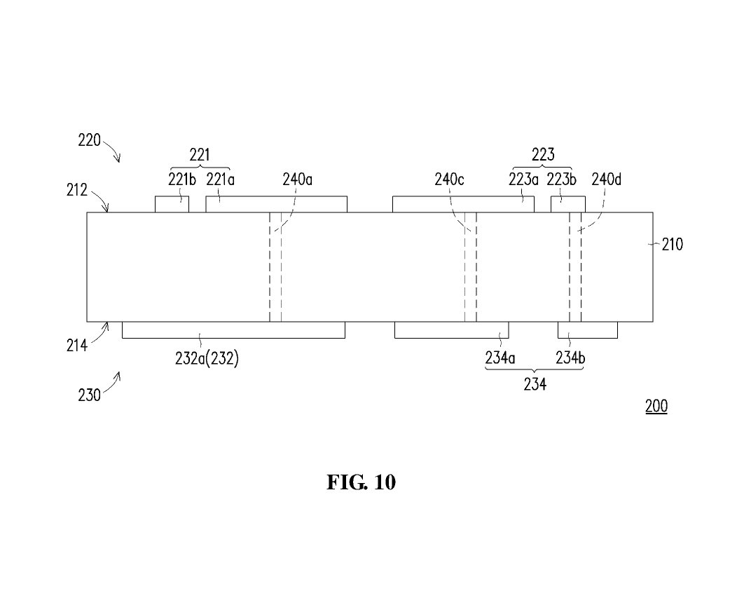

FIG. 9A and FIG. 9B are schematic top and bottom views of a circuit substrate according to the embodiment. FIG. 10 is a schematic side view of the circuit substrate as shown in FIG. 9A and FIG. 9B. Referring to FIG. 9A, FIG. 9B and FIG. 10, the circuit substrate 200 comprises an insulating base 210 and a first pattern 220. The insulating base 210 may be a plastic plate containing fiberglass, a ceramic plate or other suitable plates. Preferably, it is an aluminum nitride plate, but the present disclosure puts no limitation to the material of the insulating base 210, and the material may be decided according to practical needs. The insulating base 210 has back to back a first surface 212 and a second surface 214. The first pattern 220 is configured on the first surface 212. In addition, in the present disclosure, the circuit substrate 200 further comprises a second pattern 230 that is configured on the second surface 214. The first pattern 220 and the second pattern 230 are electrically connected through conductive posts 240a through 240f, so that the first pattern 220 acts as a contacting end of the LED chip, and the second pattern 230 act as a contacting end of the connecting lead. Besides, the first pattern 220 and the second pattern 230 have specific wiring design for providing plural sets of electric loops having integrated configuration of polarity, so as to simplify circuit configuration of a circuit mainboard at the users' side. This eliminates the needs of jumper wires and multilayer circuit structure. Herein, the term “integrated configuration of polarity” refers to a state where after die bonding on the chip, all the positive pole output ends are grouped at one side of the circuit substrate, while all the negative pole output ends are grouped at an opposite side of the circuit substrate, so that the positive pole output ends of the light emitting device are completely separated from the negative pole output ends of the light emitting device.

In the present embodiment, the insulating base has a first region, a second region, a third region and a fourth region that are arranged into an array. Particularly, referring to FIG. 9A, in the present embodiment, the insulating base 210 has the first region R1, the second region R2, the third region R3 and the fourth region R4 arranged into an array. The term “arranged into an array” refers to that fact that the regions are arranged into a matrix formed by two rows and two columns centering on the center of the insulating base 210. The first region R1, the second region R2, the third region R3 and the fourth region R4 are such arranged that they correspond to the first quadrant, the second quadrant, the third quadrant and the fourth quadrant in a planar coordinate system. That is, the first region R1 corresponds to the first quadrant, the second region R2 corresponds to the second quadrant, and so on. Thereby, the first region R1, the second region R2, the third region R3 and the fourth region R4 may be deemed as located successively anticlockwise in the upper right, upper left, lower left, lower right parts of the first surface 212.

Furthermore, in the present embodiment, the first pattern 220 comprises a first pad pair 221, a second pad pair 223, a third pad pair 225, a fourth pad pair 227 and a communicating pad 228. The first pad pair 221, the second pad pair 223, the third pad pair 225 and the fourth pad pair 227 are configured on the first region R1, the second region R2, the third region R3 and the fourth region R4, respectively. Therein, each of the pad pairs comprises a die-bonding pad and a matching pad. That is, the first pad pair 221 comprises a first die-bonding pad 221a and a first matching pad 221b, the second pad pair 223 comprises a second die-bonding pad 223a and a second matching pad 223b, the third pad pair 225 comprises a third die-bonding pad 225a and a third matching pad 225b, while the fourth pad pair 227 comprises a fourth die-bonding pad 227a and a fourth matching pad 227b. Thereby, the four sets of die-bonding pads and matching pads are paired, and successively configured in the four regions from the first quadrant to the fourth quadrant.

In the present embodiment, the first die-bonding pad 221a is adjacent to the second die-bonding pad 223a, and the third die-bonding pad 225a is adjacent to the fourth die-bonding pad 227a. That is, the first die-bonding pad 221a located in the first region R1/first quadrant and the second die-bonding pad 223a located in the second region R2/second quadrant may be deemed as arranged at two opposite sides of the Y axis of the planar coordinate system and adjacent to each other, while the first matching pad 221b and the second matching pad 223b are configured outside the first die-bonding pad 221a and the second die-bonding pad 223a, respectively and located near the opposite edges of the first surface 212. Similarly, the third die-bonding pad 225a located in the third region R3/third quadrant and the fourth die-bonding pad 227a located in the fourth region R4/fourth quadrant may be deemed as arranged at two opposite sides of the Y axis of the planar coordinate system and adjacent to each other, while the third matching pad 225b and the fourth matching pad 227b are configured outside the third die-bonding pad 225a and the fourth die-bonding pad 227a, respectively and located near the opposite edges of the first surface 212.

In addition, in the present embodiment, the first die-bonding pad 221a has an area greater than the area of the first matching pad 221b. The second die-bonding pad 223a has an area greater than the area of the second matching pad 223b. The third die-bonding pad 225a has an area greater than the area of the third matching pad 225b. The fourth die-bonding pad 227a has an area greater than the area of the fourth matching pad 227b. The term “area” refers to the planar scope the pad covers the first surface 212. In each of the pad pairs, the area of the die-bonding pad is greater than the area of the matching pad, so that when the circuit substrate 200 is latter applied to the light emitting device for working with the LED chips, the LED chips may be set in the die-bonding pads that are relatively large in terms of area in the pad pairs and connected to the corresponding matching pads by means of connecting components (e.g. wiring). However, the present disclosure is not limited to the foregoing modes, and may be modified according to practical needs.

Moreover, in the present embodiment, the communicating pad 228 is electrically connected to the first matching pad 221b and the third die-bonding pad 225a. Furthermore, the communicating pad 228 passes through a division located between the first die-bonding pad 221a and the fourth die-bonding pad 227a. Thereby, the communicating pad 228 electrically connects the third die-bonding pad 225a located in the third region R3 and the first matching pad 221b located in the first region R1, and the first die-bonding pad 221a and the fourth die-bonding pad 227a be deemed as arranged at two opposite sides of the X axis of the planar coordinate system, and separated by the communicating pad 228 to be located at two sides of the communicating pad 228. With the communicating pad 228, the LED chips set on the first pad pair 221 and electrically connected thereto are electrically connected to the LED chips set on the third pad pair 225 and electrically connected thereto, thereby forming a connected circuit.

On the other hand, referring to FIG. 9B, in the present embodiment, the second pattern 230 comprises a first electrode pair 232, a second electrode pair 234 and a third electrode pair 236. Therein, each of the electrode pairs comprises a primary electrode and a secondary electrode. That is, the first electrode pair 232 comprises a first primary electrode 232a and a first secondary electrode 232b, the second electrode pair 234 comprises a second primary electrode 234a and a second secondary electrode 234b, and the third electrode pair 236 comprises a third primary electrode 236a and a third secondary electrode 236b. The electrode pairs are configured on the second surface 214. Therein, the first primary electrode 232a is configured on the back of the first region R1, and the first secondary electrode 232b is configured on the back of the third region R3. That is, the first primary electrode 232a and the first secondary electrode 232b of the first electrode pair 232 correspond to two different regions as they are located at the back of the first region R1 and that back of the third region R3, respectively. The second primary electrode 234a and the second secondary electrode 234b of the second electrode pair 234 are configured on the back of the second region R2, and the third primary electrode 236a and the third secondary electrode 236b of the third electrode pair 236 are configured on the back of the fourth region R4.

It is thus learned that the bottom view of FIG. 9B may be understood as a 180-degree turnover of the top view of FIG. 9A against the Y axis of the planar coordinate system. That is, the second surface 214 in FIG. 9B has its upper left, upper right, lower right, lower left parts as shown successively corresponding to the first region R1, the second region R2, the third region R3 and the fourth region R4, respectively in the clockwise direction. Thereby, the first primary electrode 232a of the first electrode pair 232 corresponds to the first pad pair 221 located in the first region R1, the second electrode pair 234 (comprising the second primary electrode 234a and the second secondary electrode 234b) corresponds to the second pad pair 223 located in the second region R2, the first secondary electrode 232b of the first electrode pair 232 correspond to the third pad pair 225 located in the third region R3, and the third electrode pair 236 (comprising the third primary electrode 236a and the third secondary electrode 236b) correspond to the fourth pad pair 227 located in the fourth region R4.

Moreover, in the present embodiment, the first primary electrode 232a at the back of the first region R1, the second primary electrode 234a at the back of the second region R2, and the third secondary electrode 236b at the back of the fourth region R4 are adjacent to each other. That is, the second primary electrode 234a at the back of the second region R2 and the third secondary electrode 236b at the back of the fourth region R4 are at their places that correspond to the second region R2 and the fourth region R4 and are adjacent to the first primary electrode 232a. Similarly, the first secondary electrode 232b at the back of the third region R3, the second secondary electrode 234b at the back of the second region R2, and the third primary electrode 236a at the back of the fourth region R4 are adjacent to each other. That is, the second secondary electrode 234b at the back of the second region R2 and the third primary electrode 236a at the back of the fourth region R4 are at their places that correspond to the second region R2 and the fourth region R4 and are adjacent to the first secondary electrode 232b.

It is thus learned that in the present embodiment, the primary electrodes and the secondary electrodes may be deemed as being separated by a diagonal extending from the upper right to the lower left corners of the second surface 214 and passing through the second region R2 and the fourth region R4. Therein, the first primary electrode 232a, the second primary electrode 234a and the third secondary electrode 236b are roughly at the upper left side of the diagonal and adjacent to each other, while the first secondary electrode 232b, the second secondary electrode 234b and the third primary electrode 236a are roughly at the lower right side of the diagonal and adjacent to each other. The description related to the diagonal is merely for illustrating the relative locations of the primary electrodes and the secondary electrodes and is not intended to limit the exact locations and orientations of the primary electrodes and the secondary electrodes with respect to the diagonal. The present disclosure is not limited to the foregoing modes, and may be modified according to practical needs.

In addition, in the present embodiment, the first primary electrode 232a has its area approximately equal to the area of the first secondary electrode 232b, and the second primary electrode 234a has its area greater than the area of the second secondary electrode 234b, while the third primary electrode 236a has its area greater than the area of the third secondary electrode 236b. The term “area” refers to the planar scope the electrode covers the second surface 214. Therein, since the second primary electrode 234a and the second secondary electrode 234b correspond to the second die-bonding pad 223a located in the second region R2 (larger in area) and the second matching pad 223b (smaller in area), respectively, the second primary electrode 234a preferably has its area greater than the area of the second secondary electrode 234b. Similarly, since the third primary electrode 236a and the third secondary electrode 236b correspond to the fourth die-bonding pad 227a located in the fourth region R4 (larger in area) and the fourth matching pad 227b (smaller in area), respectively, the third primary electrode 236a preferably has its area greater than the area of the third secondary electrode 236b. In addition, since first primary electrode 232a and the first secondary electrode 232b are configured at the back of the first region R1 and the back of the third region R3, respectively, they may be equal in terms of area. However, the first primary electrode 232a and the first secondary electrode 232b may be different in terms of area. The present disclosure is not limited to the foregoing modes, and may be modified according to practical needs.

Moreover, referring to FIG. 9A, FIG. 9B and FIG. 10, in the present embodiment, the first pattern 220 and the second pattern 230 are electrically connected to each other by means of conductive posts 240a through 240f that pass through the insulating base 210 and have electric conductivity. The first pattern 220, the second pattern 230 and the conductive posts 240a through 240f may be made of silver, copper or other electrical conductive materials. The present disclosure is not limited thereto, and may be modified according to practical needs.

Particularly, in the present embodiment, since first primary electrode 232a located at the back of the first region R1, the first primary electrode 232a is electrically connected to the first die-bonding pad 221a located in the first region R1 by the conductive post 240a. Similarly, since first secondary electrode 232b is located in the back of the third region R3, the first secondary electrode 232b is electrically connected to the third matching pad 225b located in the third region R3 by the conductive post 240b. In addition, since the second primary electrode 234a and the second secondary electrode 234b are located at the back of the second region R2, and correspond to the second die-bonding pad 223a and the second matching pad 223b, respectively, the second primary electrode 234a is electrically connected to the second die-bonding pad 223a located in the second region R2 by the conductive post 240c, and the second secondary electrode 234b is electrically connected to the second matching pad 223b located in the second region R2 by the conductive post 240d. Similarly, since the third primary electrode 236a and the third secondary electrode 236b are located at the back of the fourth region R4 and correspond to the fourth die-bonding pad 227a and the fourth matching pad 227b, respectively, the third primary electrode 236a is electrically connected to the fourth die-bonding pad 227a located in the fourth region R4 by the conductive post 240e, and the third secondary electrode 236b is electrically connected to the fourth matching pad 227b located in the fourth region R4 by the conductive post 240f.

With the configuration stated above, in the present embodiment, the first die-bonding pad 221a and the first primary electrode 232a are electrically connected, and the second die-bonding pad 223a and the second matching pad 223b are electrically connected to the second primary electrode 234a and the second secondary electrode 234b, respectively, while the third matching pad 225b and the first secondary electrode 232b are electrically connected, and the fourth die-bonding pad 227a and the fourth matching pad 227b are electrically connected to the third primary electrode 236a and the third secondary electrode 236b, respectively. The first matching pad 221b, the third die-bonding pad 225a and the communicating pad 228 connecting the first matching pad 221b and the third die-bonding pad 225a are not electrically connected to the second pattern 230 by means of the conductive posts. Thereby, when the circuit substrate 200 is used in a light emitting device, the six conductive posts 240a through 240f have each two thereof connected to positive electricity and negative electricity so as to constitute an electric loop, so the circuit substrate 200 provides three sets of electric loops.

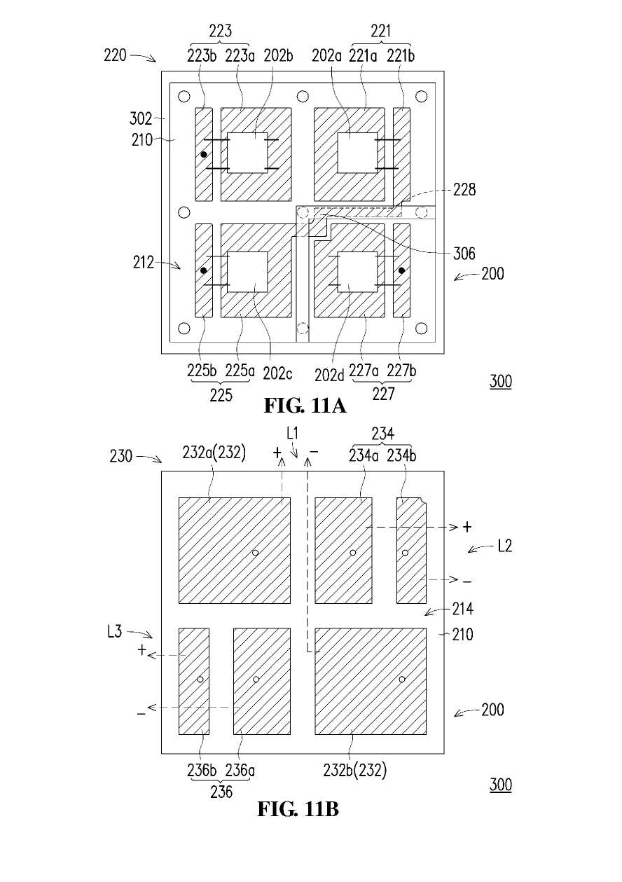

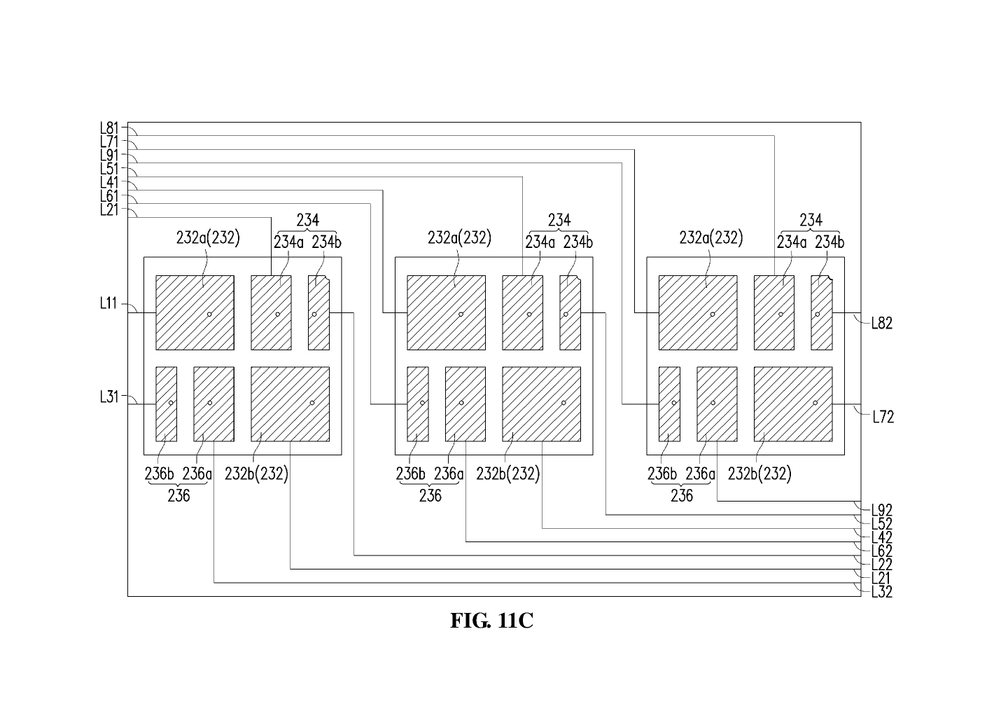

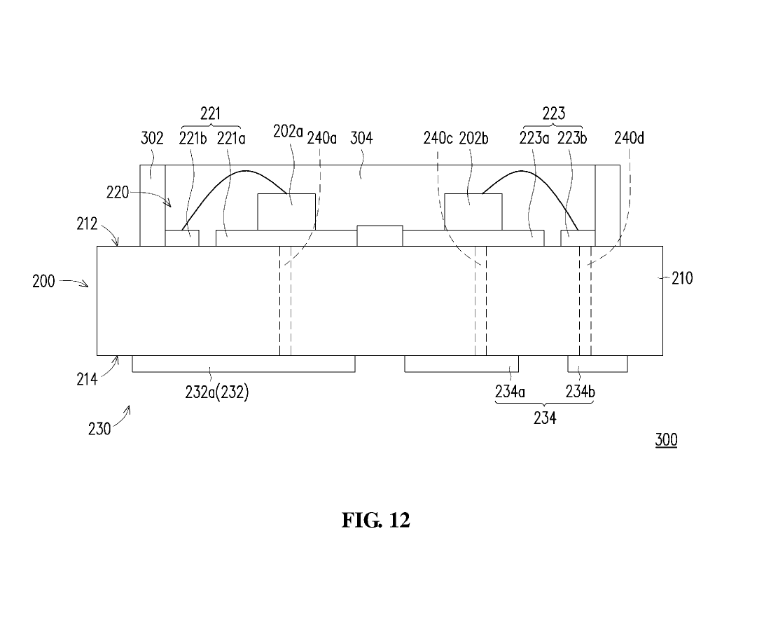

FIG. 11A and FIG. 11B are schematic top and bottom views of the circuit substrate as shown in FIG. 9A and FIG. 9B applied to a light emitting device. FIG. 11C is a schematic circuit diagram of a lamp using the light emitting device of FIG. 11B. FIG. 12 is a schematic side view of the light emitting device as shown in FIG. 11A through FIG. 11C. Since the light emitting device 300 and the circuit substrate 200 are usually formed on the same circuit mainboard in the same process (including pattern forming, LED chip setting and other steps) to produce plural units that are subsequently cut into the individual unit as shown in FIG. 11A, FIG. 11B and FIG. 12, three light emitting devices 300 as shown in FIG. 11B are depicted in FIG. 11C to clearly illustrate how the connecting leads are configured.

Referring to FIG. 11A through FIG. 12, in the present example, the light emitting device 300 comprises the circuit substrate 200 and one or more LED chips. The LED chips may each be configured on one of the first die-bonding pad 221a, the second die-bonding pad 223a, the third die-bonding pad 225a and the fourth die-bonding pad 227a. Furthermore, the light emitting device 300 comprises a first LED chip 202a, the second LED chip 202b, the third LED chip 202c and the fourth LED chip 202d, and the first LED chip 202a, the second LED chip 202b, the third LED chip 202c, the fourth LED chip 202d are configured on the first die-bonding pad 221a, the second die-bonding pad 223a, the third die-bonding pad 225a and the fourth die-bonding pad 227a, respectively. However, the present disclosure puts no limitation of the amount of LED chips, and the amount may vary according to practical needs. In addition, the light emitting device 300 further comprises a circular retaining wall 302 and an encapsulation compound 304. The circular retaining wall 302 circles the one or more LED chips and contains a reflective material, such as boron nitride (BN), titanium dioxide (TiO2), and zirconium oxide (ZnO), so as to collect the light emitted by the LED chips. Moreover, the encapsulation compound 304 covers the LED chips and fills up the circular retaining wall 302, so as to pack the LED chips therein.

Particularly, as shown in FIG. 11A, in the present embodiment, the first LED chip 202a may be a red-light chip, which is configured on the first die-bonding pad 221a and electrically connected to the first die-bonding pad 221a through a positive electrode at its bottom (not shown) while having a negative electrode at its top (not shown) electrically connected to the first matching pad 221b by means of connecting components (e.g. wiring). Similarly, the third LED chip 202c may be a red-light chip, which is configured on third die-bonding pad 225a and electrically connected to the third die-bonding pad 225a through a positive electrode at its bottom (not shown) while having a negative electrode at its top (not shown) electrically connected to the third matching pad 225b by means of connecting components (e.g. wiring). Thereby, the first LED chip 202a and the first pad pair 221 are electrically connected, while the third LED chip 202c and the third pad pair 135 are electrically connected.

In addition, in the present embodiment, since the first matching pad 221b and the third die-bonding pad 225a are electrically connected through the communicating pad 228, and the first die-bonding pad 221a and the third matching pad 225b are electrically connected to the first primary electrode 232a and the first secondary electrode 232b of the second surface 214, respectively, the first LED chip 202a, the first pad pair 221, the third LED chip 202c, the third pad pair 135 and the first electrode pair 232 are electrically connected to each other and constitute a first set of electric loop L1 (as shown in FIG. 11B), wherein the first primary electrode 232a is suitable to act as the positive end of the electric loop L1 for connecting electropositivity, and the first secondary electrode 232b is suitable to act as the negative end of the electric loop L1 for connecting electronegativity. The first LED chip 202a and the third LED chip 202c are electrically connected in series in the electric loop L1.

Moreover, as shown in FIG. 11A, the second LED chip 202b may be a blue-light chip, which is configured on the second die-bonding pad 223a, and has its positive and negative electrodes at the top (not shown) electrically connected to the second die-bonding pad 223a and the second matching pad 223b, respectively, by means of wiring. Thereby, the second LED chip 202b and the second pad pair 223 are electrically connected, and the second die-bonding pad 223a and the second matching pad 223b of the second pad pair 223 are electrically connected to the second primary electrode 234a and the second secondary electrode 234b of the second surface 214, respectively. Thereby, the second LED chip 202b, the second pad pair 223 and the second electrode pair 234 are electrically connected to each other, so as to constitute a second set of electric loop L2 (as shown in FIG. 11B), wherein the second primary electrode 234a is suitable to act as the positive end of the electric loop L2 for connecting electropositivity, and the second secondary electrode 234b is suitable to act as the negative end of the electric loop L2 for connecting electronegativity.

Similarly, as shown in FIG. 11A, the fourth LED chip 202d may be a blue-light chip, which is configured on the fourth die-bonding pad 227a, and has its positive and negative electrodes at the top (not shown) electrically connected to the fourth die-bonding pad 227a and the fourth matching pad 227b, respectively. Thereby, the fourth LED chip 202d and the fourth pad pair 227 are electrically connected, while the fourth die-bonding pad 227a and the fourth matching pad 227b of the fourth pad pair 227 are further electrically connected to the third primary electrode 236a and the third secondary electrode 236b of the second surface 214, respectively. Thereby, the fourth LED chip 202d, the fourth pad pair 227 and the third electrode pair 236 are electrically connected to each other, so as to constitute a third set of electric loop L3 (as shown in FIG. 11B), wherein the third primary electrode 236a is suitable to act as the negative end of the electric loop L3 for connecting electronegativity, and the third secondary electrode 236b is suitable to act as the positive end of the electric loop L3 for connecting electropositivity.

With the configuration stated above, in the present embodiment, as described previously, based on the diagonal extending from the upper right to the lower left parts of the second surface 214 and passing through the second region R2 and the fourth region R4, the first primary electrode 232a, the second primary electrode 234a and the third secondary electrode 236b are roughly at the upper left side of the diagonal and adjacent to each other, while the first secondary electrode 232b, the second secondary electrode 234b and the third primary electrode 236a are roughly at the lower right side of the diagonal and adjacent to each other. Therein, as shown in FIG. 11C, the first primary electrode 232a, the second primary electrode 234a and the third secondary electrode 236b are of one polarity (each acting as the positive ends of the electric loops L1 through L3 and suitable for connected electropositivity), while the first secondary electrode 232b, the second secondary electrode 234b and the third primary electrode 236a are of the other polarity (each acting as the negative ends of the electric loops L1 through L3 and suitable for connected electronegativity).

At this time, since the first primary electrode 232a, the second primary electrode 234a and the third secondary electrode 236b acting as the positive ends are located at the upper left side of the diagonal and adjacent to each other, they are grouped at the upper left side of the circuit substrate/the insulating base 210. Thus, connecting leads (as the connecting leads L11, L21, L31, L41, L51, L61, L71, L81, L91 shown in FIG. 11C) for connecting the positive end may be extended outward from the same lateral of the second surface 214 of the insulating base 210 (as shown in FIG. 11C, extended outward from the left lateral of the second surface 214 corresponding to the first primary electrode 232a), and connected to electropositivity. Similarly, since the first secondary electrode 232b, the second secondary electrode 234b and the third primary electrode 236a acting as the negative ends are located at the lower right side of the diagonal and adjacent to each other, they are grouped at the lower right side of the circuit substrate/the insulating base 210. Thus, connecting lead (as the connecting leads L12, L22, L32, L42, L52, L62, L72, L82, L92 shown in FIG. 11C) for connecting the negative end may be extended outward from the same lateral of the second surface 214 of the insulating base 210 (as shown in FIG. 11C, extended outward from the right lateral of the second surface 214 corresponding to the first secondary electrode 232b), and connected to electronegativity. Thereby, the connecting leads L11, L21, L31, L41, L51, L61, L71, L81, L91 for connecting the positive ends (the first primary electrode 232a, the second primary electrode 234a and the third secondary electrode 236b) have no interference with the connecting leads L12, L22, L32, L42, L52, L62, L72, L82, L92 for connecting the negative ends (the first primary electrode 232a, the second primary electrode 234a and the third secondary electrode 236b), without the need of using any jumper wires or multilayer circuit structures to prevent short circuit. It is thus learned that the second pattern 230 such designed is favorable to subsequent wire configuration.

Additionally, where vertical chips are used, since this type of chips has its die-bonding surface an electrically conductive surface, in the process of die bonding, the polarity of the die-bonding surface and the die-bonding pads to be used has to be considered in order to achieve integrated configuration of polarity. In the present embodiment, the first LED chip 202a and the third LED chip 202c are red-light chips, and the second LED chip 202b and the fourth LED chip 202d are blue-light chips. Therein, the red-light chip exemplificatively has its positive electrode at the bottom, and has its negative electrode at the top. When the light emitting device 300 uses such a red-light chip, the red-light chip is preferably configured on the electrically positive die-bonding pad, so that the positive electrode at its bottom is directly connected to the electrically positive die-bonding pad, and then the negative electrode is connected to the electrically negative matching pad through wiring. Comparatively, the blue-light chip is a horizontal chip with its positive and negative electrodes both at its top, so it may be configured on a die-bonding pad of any polarity, and have its positive and negative electrodes connected to the die-bonding pad and the matching pad, respectively, through wiring.

Thereby, the red-light chip as shown in the present embodiment having its positive electrode at the bottom is suitable to be configured on the first die-bonding pad 221a, the second die-bonding pad 223a or the third die-bonding pad 225a. In the present embodiment, the red-light chips are configured on the first die-bonding pad 221a and the third die-bonding pad 225a. Comparatively, the blue-light chip is suitable to be configured on any of the four die-bonding pads. In the present embodiment, the blue-light chips are configured on the second die-bonding pad 223a and the fourth die-bonding pad 227a. However, the present disclosure puts no limitation to the type and amount of the LED chips, and these variables may be determined according to practical needs. Therein, since fourth die-bonding pad 227a is electrically connected to the third primary electrode 236a to make it electrically negative, the fourth die-bonding pad 227a is not suitable for connecting a red-light chip having its positive electrode at the bottom as exemplificatively described above. It is thus learned that when the circuit substrate 200 of the present embodiment is used in the light emitting device 300, it may have four blue-light chips as the LED chips so that the light emitting device provides monochromatic light. Alternatively, it may have plural red-light chips and at least one blue-light chip (configured on the fourth die-bonding pad 227a) for providing mixed color light.

In addition, when the light emitting device 300 uses the blue chip, it may be adjusted to provide white light as needed. Particularly, in the present embodiment, one of the second LED chip 202b and the fourth LED chip 202d, taking the fourth LED chip 202d for example herein, is covered by a layer of fluorescent powder. Therein, the fluorescent powder layer may be made of yellow fluorescent powder or other suitable colors of fluorescent powder. The preferable fluorescent powder is as described in the first aspect. The fluorescent powder layer is laid on the fourth LED chip 202d, so that the blue light emitted by the fourth LED chip 202d is mixed in the fluorescent powder layer before emitted, so as to provide white light. Moreover, the light emitting device 300 comprises circular sub retaining wall 306, which circles the LED chip covered by the fluorescent powder layer, namely the fourth LED chip 202d. The circular sub retaining wall 306 comprises a reflective material. The purpose of the circular sub retaining wall 306 is to prevent laying of the fluorescent powder layer from affecting the other LED chips. That is, the circular sub retaining wall 306 prevents the fluorescent powder layer from overflowing to any LED chips other than the fourth LED chip 202d. In addition, the reflective material it contains helps to collecting the light emitted by the fourth LED chip 202d. However, the present disclosure puts no limitation to whether the fluorescent powder layer and the circular sub retaining wall 306 are included, and use of these components may be decided according to practical needs.

Moreover, based on the light emitting device 300, the scheme for modulating voltage drops as described in the first or second aspect may be further adopted. In particular, bonding adhesive is provided between the LED chips and the corresponding die-bonding pads to change the voltage drops of the LED chips. Specifically, in the embodiment of FIG. 11A, with addition of the disclosed bonding adhesive, the voltage drops of the electric loops are substantively increased linearly with the amount of the LED chips. In the device 300, the voltage drop of the electric loop L1 is about twice of that of the electric loops L2 and L3. When plural said light emitting devices are used in a lamp, as shown in FIG. 11C, a user may conveniently connect two said electric loops L2 in series, connect two said electric loops L3 in series or connect one said electric loop L1 with one said electric loop L3 in series to level the voltage drop with that of the electric loop L1. Thereby, work circuits having the same voltage drop can be achieved using a simple combination, and this in turn allows use of a single external power source to perform control.

The above description merely reflects one possible aspect of the present disclosure, and the present disclosure is not limited to using the modulating scheme in the foregoing light emitting device 300. To state clearly, use of the design of the circuit substrate described in the present aspect shall be also within the scope of the present disclosure.

With the configuration stated above, the circuit substrate 200 and the light emitting device 300 of the present embodiment are suitable for providing plural sets of electric loops L1 through L3 having integrated configuration of polarity, so as to simplify circuit configuration of a circuit mainboard at the users' side. This eliminates the needs of jumper wires and multilayer circuit structure. One or more LED chips may be connected thereto, and the chips may be red-light chips or blue-light chips according to practical needs, so that the light emitting device 300 emits monochromatic light or mixed color light as a combination of rays of various bands. Thereby, work circuits having the same voltage drop can be achieved using a simple combination, and this in turn allows use of a single external power source to perform control.

The above description explains the spirit and principle of the scheme for modulating voltage drops by referring to the third aspect of the present disclosure, and more aspects will be further provided below.

### <Fourth Aspect>

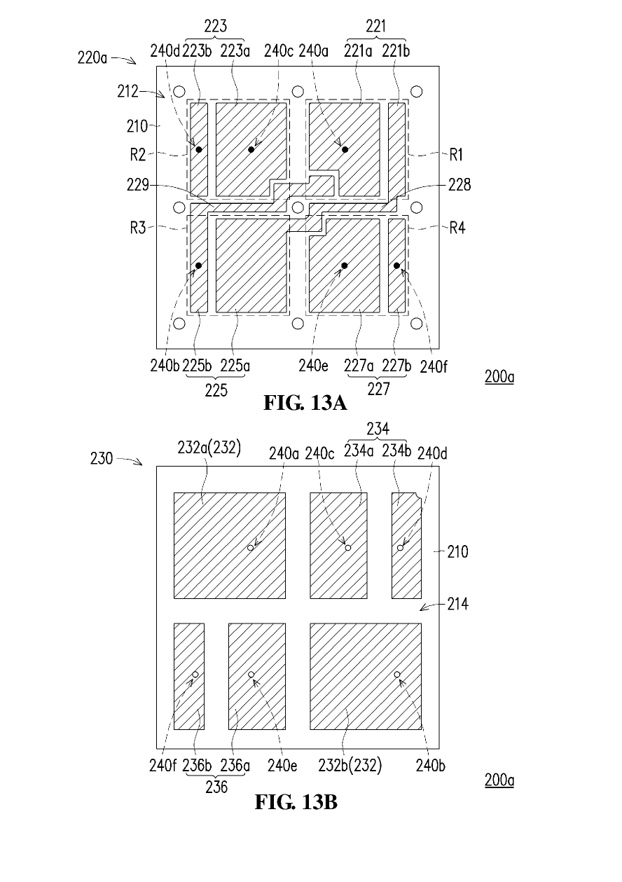

FIG. 13A and FIG. 13B are schematic top and bottom views of a circuit substrate according to another embodiment of the present disclosure. Referring to FIG. 13A through FIG. 13B, in the present embodiment, In addition, in the present embodiment, the circuit substrate 200a and the foregoing circuit substrate 200 are similar in terms of structure and function, so the implement of the circuit substrate 200a may be referred to that of the foregoing circuit substrate 200 (as shown in FIG. 9A through FIG. 10). The main difference between the circuit substrate 200a and the foregoing circuit substrate 200 is that the first pattern 220a of the present embodiment is different from the foregoing first pattern 220.

Particularly, in the present embodiment, the first pattern 220a further comprises an extended pad 229 configured on the first surface 212. The extended pad 229 is adjacent to one lateral of the first die-bonding pad 221a and electrically connected to the third matching pad 225b. Furthermore, the extended pad 229 passes through a division located between the second die-bonding pad 223a and the third die-bonding pad 225a. Thereby, the extended pad 229 is connected to the third matching pad 225b located in the third region R3 and extends from the third region R3 to the first region R1 so as to be adjacent to the first die-bonding pad 221a located in the first region R1. The second die-bonding pad 223a and the third die-bonding pad 225a may be deemed as arranged at two opposite sides of the X axis of the planar coordinate system, and separated by the extended pad 229 so as to be located at two opposite sides of the extended pad 229. The extended pad 229 may electrically connect protective elements, such as Zener diodes. However, the present disclosure puts no limitation on whether the extended pad 229 and the protective elements are included, and the use of such components may be decided according to practical needs. Particularly, the protective element may be deposited on the extended pad or the first die-bonding pad and electrically connected to the extended pad and the first die-bonding pad, thereby protecting the electric loop L1.

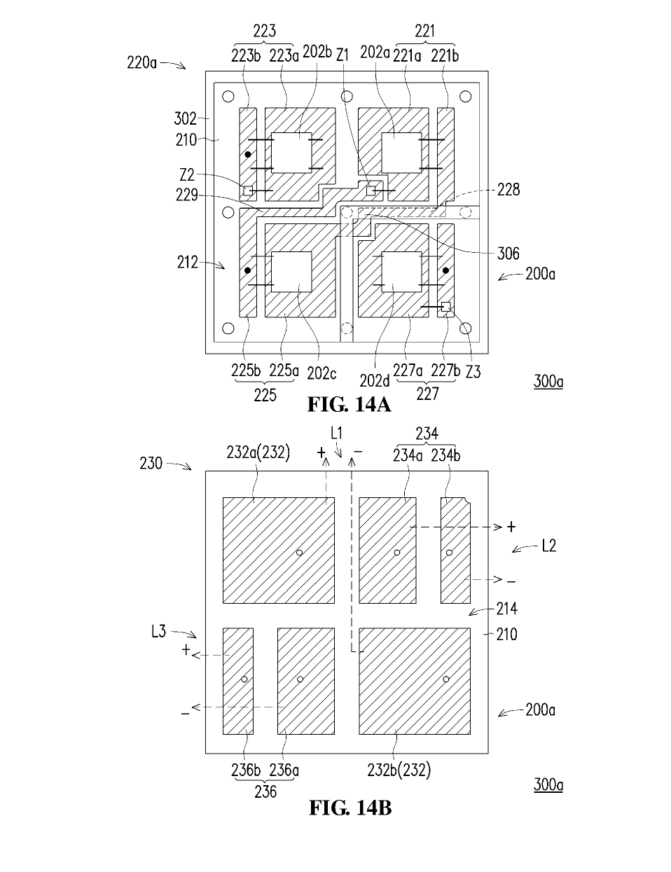

FIG. 14A and FIG. 14B are schematic top and bottom views of the circuit substrate as shown in FIG. 13A and FIG. 13B applied to a light emitting device. Referring to FIG. 14A through FIG. 14B, in the present example, the light emitting device 300a and the foregoing light emitting device 300 are similar in terms of structure and effect, so the implement of the light emitting device 300a may be referred to that of the foregoing light emitting device 300 (as shown in FIG. 11A through FIG. 14). The main difference is that the light emitting device 300a of the present embodiment comprises the foregoing circuit substrate 200a (comprising the extended pad 229). The three electric loops L1 through L3 may further include the foregoing Zener diodes as protective elements. For example, the Zener diode Z1 is configured on the extended pad 229 and electrically connected to the third matching pad 225b, and further electrically connected to the first die-bonding pad 221a through wiring. Thereby, the Zener diode Z1 is electrically connected to the first primary electrode 232a acting as the positive end of the electric loop L1 through the first die-bonding pad 221a, and electrically connected to the first secondary electrode 232b acting as the negative end of the electric loop L1 through the extended pad 229 and the third matching pad 225b. Similarly, the Zener diode Z2 is configured on the second matching pad 223b, and electrically connected to the second die-bonding pad 223a through wiring. Thereby, the Zener diode Z2 is electrically connected to the second primary electrode 234a acting as the positive end of the electric loop L2 through the second die-bonding pad 223a, and electrically connected to the second secondary electrode 234b acting as the negative end of the electric loop L2 through the third matching pad 225b. The Zener diode Z3 is configured on the fourth matching pad 227b, and electrically connected to the fourth die-bonding pad 227a through wiring, so that it is electrically connected to the third primary electrode 236a acting as the negative end of the electric loop L3 through the fourth die-bonding pad 227a, and is electrically connected to the third secondary electrode 236b acting as the positive end of the electric loop L3 through the fourth matching pad 227b.

The pads on which the Zener diodes Z1 through Z3 are configured and the pads on which the wiring is made may be individually interchanged, as long as the equivalent electric loop is formed. In other words, the Zener diode Z1 may be configured on the first die-bonding pad 221a and wired to the extended pad 229 and electrically connected to third matching pad 225b. Alternatively, the Zener diode Z2 may be configured on the second die-bonding pad 223a, and electrically connected to the second matching pad 223b through wiring. Alternatively, the Zener diode Z3 may be configured on the fourth die-bonding pad 227a and electrically connected to fourth matching pad 227b through wiring. All these variations are within the scope of the present disclosure. Additionally, in one embodiment without the extended pad 229 (such as the embodiment depicted in FIG. 10A through FIG. 10C), the electric loops L1 through L3 may include the foregoing Zener diodes or other suitable protective elements. The present disclosure is not limited thereto. Except provision of the extended pad 229 and the Zener diodes Z1 through Z3, the light emitting device 300a/circuit substrate 200a and the foregoing light emitting device 300/circuit substrate 200 are similar in terms of structure and effect. Thus, it also has the benefits provided by the design of the second pattern 230, thereby eliminating the need of using any jumper wires or multilayer circuit structures to prevent short circuit and is favorable to subsequent wire configuration. Thereby, work circuits having the same voltage drop can be achieved using a simple combination, and this in turn allows use of a single external power source to perform control.

### <Fifth Aspect>

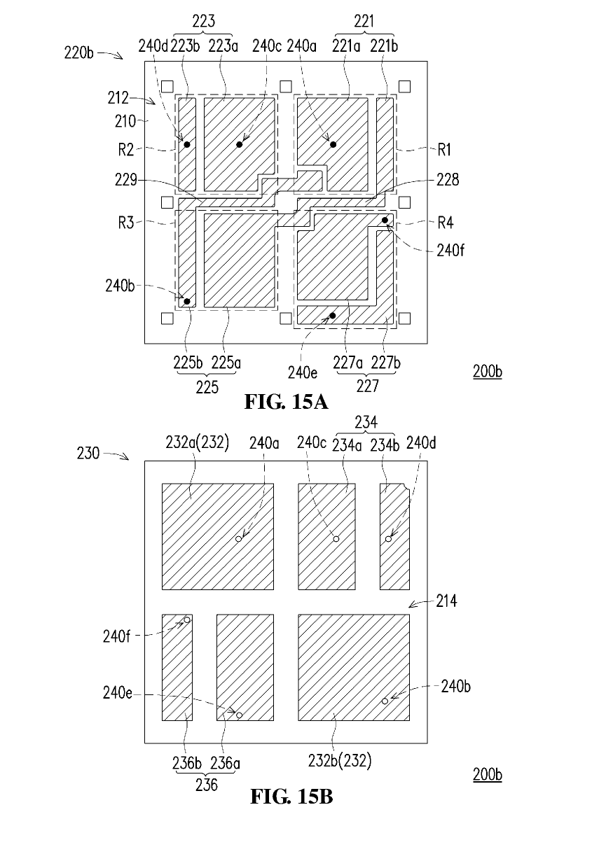

FIG. 15A and FIG. 15B are schematic top and bottom views of a circuit substrate according to yet another embodiment of the present disclosure. Referring to FIG. 15A through FIG. 15B, in the present embodiment, the circuit substrate 200b and the foregoing circuit substrates 200 and 200a are similar in terms of structure, so the side view thereof may be deemed as that shown in FIG. 10. The circuit substrate 200b comprises an insulating base 210, a first pattern 220b, and a second pattern 230. The structure, material and design (the four regions arranged into an array) of the insulating base 210 may be referred to the foregoing description and no repetition is made herein. The first pattern 220b and the second pattern 230 are configured on the first surface 212 and the second surface 214 of the insulating base 210, respectively, and electrically connected by means of conductive posts 240a through 240f that pass through the insulating base 210 and have electric conductivity, so that the first pattern 220b acts as the contacting end of the LED chips, while the second pattern 230 act as the contacting end of the connecting leads. The first pattern 220b and the second pattern 230 are specially designed to provide plural sets of electric loops having integrated configuration of polarity, so as to simplify circuit configuration of a circuit mainboard at the users' side. This eliminates the needs of jumper wires and multilayer circuit structure.

Particularly, in the present embodiment, the first pattern 220b comprises a first pad pair 221, a second pad pair 223, a third pad pair 225, a fourth pad pair 227, a communicating pad 228 and an extended pad 229. The first pad pair 221, the second pad pair 223, the third pad pair 225, and the fourth pad pair 227 are configured on the first region R1, the second region R2, the third region R3 and the fourth region R4, respectively, and each of the pad pairs comprises a die-bonding pad and a matching pad. The relative location between the die-bonding pad and the matching pad can be seen in the description of the previous embodiment. Moreover, the communicating pad 228 passes through a division located between the first die-bonding pad 221a and the fourth die-bonding pad 227a and connects the third die-bonding pad 225a located in third region R3 and the first matching pad 221b located in the first region R1. The extended pad 229 passes through a division located between the second die-bonding pad 223a and the third die-bonding pad 225a and connects the third matching pad 225b located in the third region R3 and extends to be adjacent to the first die-bonding pad 221a located in the first region R1. It is thus learned that the first pattern 220b of the present embodiment are similar to the foregoing first patterns 220 and 120a, so its structure and design may be seen in the foregoing, and no repetition is made herein.

Similarly, the second pattern 230 comprises a first electrode pair 232, a second electrode pair 234 and a third electrode pair 236. Each of the electrode pairs comprises a primary electrode and a secondary electrode. The first primary electrode 232a configured at the back of first region R1, the second primary electrode 234a configured at the back of the second region R2, and the third secondary electrode 236b configured at the back of the fourth region R4 are adjacent to each other. The first secondary electrode 232b configured at the back of the third region R3, the second secondary electrode 234b configured at the back of the second region R2, and the third primary electrode 236a configured at the back of the fourth region R4 are adjacent to each other. It is thus learned that the second pattern 230 of the present embodiment is similar to its counterparts described previously, so its structure and design may be seen in the foregoing, and no repetition is made herein.

With the configuration stated above, in the present embodiment, the circuit substrate 200b is similar to the foregoing circuit substrates 200 and 200a in terms of structure and design, with the only difference laid on how the fourth pad pair 227 located in the fourth region R4 and the third electrode pair 236 located at the back of the fourth region R4 are connected.

In detail, in the present embodiment, the first primary electrode 232a is electrically connected to the first die-bonding pad 221a located in the first region R1 through the conductive post 240a, while the first secondary electrode 232b is electrically connected to the third matching pad 225b located in the third region R3 through the conductive post 240b. Similarly, the second primary electrode 234a is electrically connected to the second die-bonding pad 223a located in the first region R1 through the conductive post 240c, while the second secondary electrode 234b is electrically connected to the second matching pad 223b located in the first region R1 through the conductive post 240d. However, while the third primary electrode 236a and the third secondary electrode 236b are located at the back of the fourth region R4 and correspond to the fourth die-bonding pad 227a and the fourth matching pad 227b, respectively, in the present embodiment, the third primary electrode 236a is not connected to the fourth die-bonding pad 227a, and the third secondary electrode 236b is not connected to the fourth matching pad 227b. Instead, in the present embodiment, the third primary electrode 236a and the fourth matching pad 227b are electrically connected through the conductive post 240e, and the third secondary electrode 236b and the fourth die-bonding pad 227a are electrically connected through the conductive post 240f. The connection may be realized by designing the fourth die-bonding pad 227a and the fourth matching pad 227b into specific geometry so that their local parts correspond to the third secondary electrode 236b and the third primary electrode 236a, respectively.

With the configuration stated above, in the present embodiment, the first die-bonding pad 221a and the first primary electrode 232a are electrically connected. The second die-bonding pad 223a and the second matching pad 223b are electrically connected and the second primary electrode 234a and the second secondary electrode 234b, respectively. The third matching pad 225b and the first secondary electrode 232b are electrically connected. The fourth die-bonding pad 227a and the fourth matching pad 227b are electrically connected to the third secondary electrode 236b and the third primary electrode 236a, respectively. The first matching pad 221b, the third die-bonding pad 225a and the communicating pad 228 connecting the first matching pad 221b and the third die-bonding pad 225a are not electrically connected to the second pattern 230 through the conductive post. Thereby, when the circuit substrate 200a is used in a light emitting device, the six conductive posts 240a through 240f have each two thereof connected to positive electricity and negative electricity so as to constitute an electric loop, so the circuit substrate 200a provides three sets of electric loops.

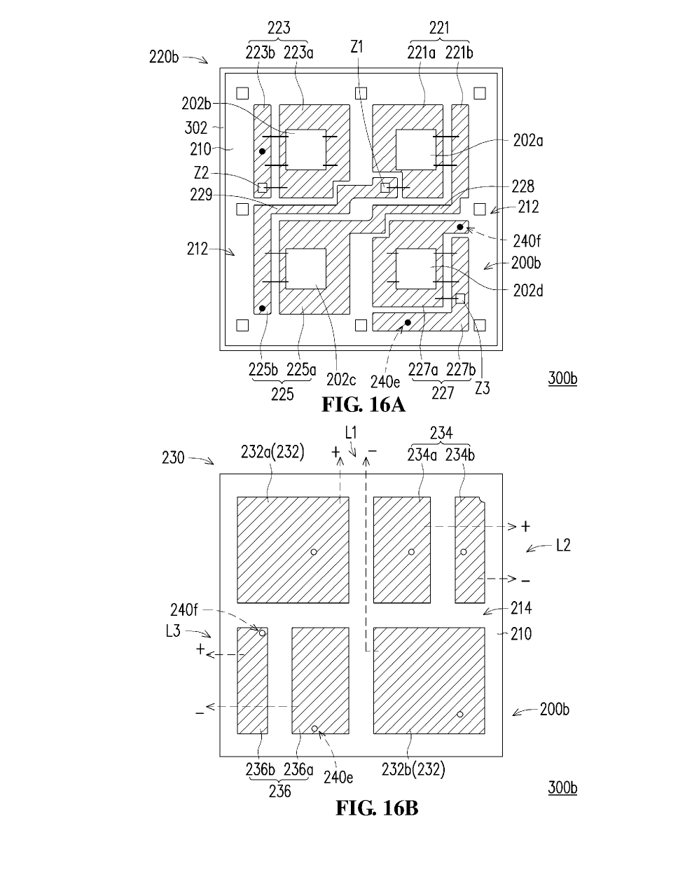

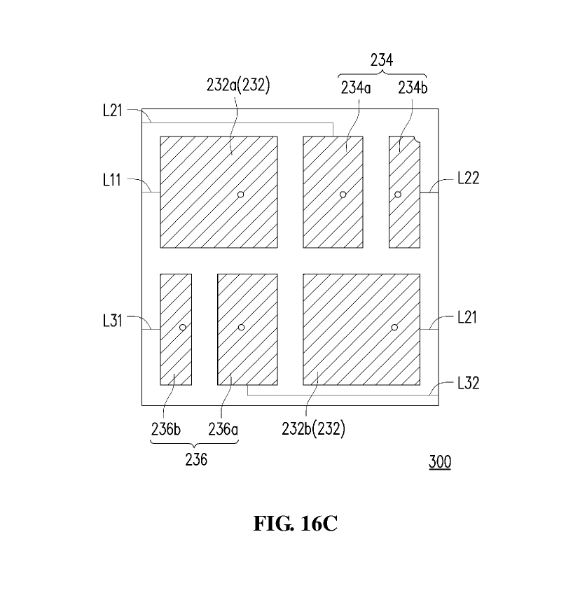

FIG. 16A and FIG. 16B are schematic top and bottom views of the circuit substrate as shown in FIG. 15A and FIG. 15B applied to a light emitting device. FIG. 16C is a schematic circuit diagram of a lamp using the light emitting device of FIG. 16B. Referring to FIG. 16A through FIG. 16C, in the present example, the light emitting device 300b comprises the circuit substrate 200b and one or more LED chips. The LED chips may be each configured on one of the first die-bonding pad 221a, the second die-bonding pad 223a, the third die-bonding pad 225a and the fourth die-bonding pad 227a. Thereby, the light emitting device 300b is similar to the foregoing light emitting devices 300 and 300a, so its structure may be seen in the foregoing, and no repetition is made herein. The main difference between the light emitting device 300b and the light emitting devices 300 and 300a is that the light emitting device 300b uses the circuit substrate 200b.

In detail, as shown in FIG. 16A, in the present embodiment, the first LED chip 202a is configured on the first die-bonding pad 221a, and electrically connected to the first pad pair 221. The third LED chip 202c is configured on the third die-bonding pad 225a, and electrically connected to the third pad pair 135. In addition, the first matching pad 221b and the third die-bonding pad 225a are electrically connected through the communicating pad 228, and the first die-bonding pad 221a and the third matching pad 225b are further electrically connected to the first primary electrode 232a and the first secondary electrode 232b, respectively. Thereby, the first LED chip 202a, the first pad pair 221, the third LED chip 202c, the third pad pair 135 and the first electrode pair 232 electrically connected to each other, so as to constitute a first set of electric loop L1 (as shown in FIG. 16B), wherein the first primary electrode 232a is suitable to act as the positive end of the electric loop L1 for connecting electropositivity, while the first secondary electrode 232b is suitable to act as the negative end of the electric loop L1 for connecting electronegativity. The first LED chip 202a and the third LED chip 202c are electrically connected in series in the electric loop L1.

Moreover, as shown in FIG. 16A, in the present embodiment, the second LED chip 202b is configured on the second die-bonding pad 223a, and electrically connected to the second pad pair 223. The second die-bonding pad 223a and the second matching pad 223b of the second pad pair 223 are further electrically connected to the second primary electrode 234a and the second secondary electrode 234b, respectively. Thereby, the second LED chip 202b, the second pad pair 223 and the second electrode pair 234 electrically connected to each other, so as to constitute a second set of electric loop L2 (as shown in FIG. 16B), wherein the second primary electrode 234a is suitable to act as the positive end of the electric loop L2 for connecting electropositivity, while the second secondary electrode 234b is suitable to act as the negative end of the electric loop L2 for connecting electronegativity.

In addition, as shown in FIG. 16A, in the present embodiment, the fourth LED chip 202d is configured on the fourth die-bonding pad 227a, and electrically connected to the fourth pad pair 227. The fourth die-bonding pad 227a and the fourth matching pad 227b of the fourth pad pair 227 are further respectively electrically connected to the third primary electrode 236a and the third secondary electrode 236b of the second surface 214. Thereby, the fourth LED chip 202d, the fourth pad pair 227 and the third electrode pair 236 electrically connected to each other, so as to constitute a third set of electric loop L3 (as shown in FIG. 16B). Therein, the third primary electrode 236a is suitable to act as the negative end of the electric loop L3 for connecting electronegativity, while the third secondary electrode 236b is suitable to act as the positive end of the electric loop L3 for connecting electropositivity.

With the configuration stated above, in the present embodiment, as described previously, based on the diagonal extending from the upper right to the lower left parts of the second surface 214 and passing through the second region R2 and the fourth region R4, the first primary electrode 232a, the second primary electrode 234a and the third secondary electrode 236b are roughly at the upper left side of the diagonal and adjacent to each other, while the first secondary electrode 232b, the second secondary electrode 234b and the third primary electrode 236a are roughly at the lower right side of the diagonal and adjacent to each other. Therein, as shown in FIG. 16C, the first primary electrode 232a, the second primary electrode 234a and the third secondary electrode 236b adjacent to each other are of the same polarity (acting as the positive ends of the electric loops L1 through L3, respectively, for connecting electropositivity), and the first secondary electrode 232b, the second secondary electrode 234b and the third primary electrode 236a adjacent to each other are the other polarity (acting as the negative ends of the electric loops L1 through L3, respectively, for connecting electronegativity).

Thereby, since the first primary electrode 232a, the second primary electrode 234a and the third secondary electrode 236b acting as the positive ends are located in the upper left side of the diagonal and adjacent to each other (grouped at the upper left side of the circuit substrate/the insulating base 210), and the first secondary electrode 232b, the second secondary electrode 234b and the third primary electrode 236a acting as the negative ends are located in the lower right side of the diagonal and adjacent to each other (grouped at the lower right side of the circuit substrate/the insulating base 210). Thus, connecting lead (as the connecting leads L11, L21, L31 as shown in FIG. 16C) for connecting the positive ends may be extended outward from the same lateral of the second surface 214 (as shown in FIG. 16C, extended outward from the left lateral of the second surface 214 corresponding to the first primary electrode 232a), and connected to electropositivity. The connecting leads L12, L22, L32 for connecting the negative ends (the connecting leads L12, L22, L32 as shown in FIG. 16C) may be extended outward from the same lateral of the second surface 214 (as shown in FIG. 16C, extended outward from the right lateral of the second surface 214 corresponds to the first secondary electrode 232b), and connected to electronegativity. Thereby, the connecting leads L11, L21, L31 for connecting the positive ends (the first primary electrode 232a, the second primary electrode 234a and the third secondary electrode 236b) have no interference with the connecting leads L12, L22, L32, for connecting the negative ends (the first primary electrode 232a, the second primary electrode 234a and the third secondary electrode 236b), without the need of using any jumper wires or multilayer circuit structures to prevent short circuit.

It is thus learned that in the present embodiment, the circuit substrate 200b is similar to the foregoing circuit substrates 200 and 200a in terms design of the second pattern 230, and when it is used in the light emitting device 300b, the second pattern 230 is electrically connected to the connecting leads in the manner as that described in the previous embodiment the. However, in the present embodiment, the fourth pad pair 227 and the third electrode pair 236 of the circuit substrate 200b are connected differently from that seen in the previous embodiment. Particularly, the fourth die-bonding pad 227a is electrically connected to the third primary electrode 236a acting as the positive end, and the fourth matching pad 227b is electrically connected to the third secondary electrode 236b acting as the negative end. Thereby, in the present embodiment, the fourth die-bonding pad 227a is electrically positive, and the fourth matching pad 227b is electrically negative. With this design, the four die-bonding pads of the circuit substrate 200b of the present embodiment are all electrically positive, while the four matching pads are all electrically negative. Thus, the four die-bonding pads of the present embodiment may freely use red-light chips and blue-light chips according to practical needs.

In detail, as described previously, the red-light chip has its positive electrode provided on the bottom, and has its negative electrode provided on the top. When the light emitting device 300b uses such a red-light chip, the red-light chip is preferably configured on the electrically positive die-bonding pad, so that the positive electrode at the bottom is directly connected to the die-bonding pad, and then the negative electrode is connected to the matching pad through wiring. Comparatively, the blue-light chip has its positive and negative electrodes both on the top, so it may be configured on a die-bonding pad of any of the polarity, and have the positive and negative electrodes connected to the die-bonding pad and the matching pad through wiring. Thereby, in the present embodiment, the light emitting device 300b may use two red-light chips and two blue-light chips as those seen in the foregoing light emitting device 300. For example, the first LED chip 202a and the third LED chip 202c are red-light chips, while the second LED chip 202b and the fourth LED chip 202d are blue-light chips. However, in other embodiments not shown herein, the circuit substrate 200b may alternatively carry four blue-light chips or four red-light chips, and the present disclosure is not limited thereto.

It is thus learned that when the circuit substrate 200b of the present embodiment is used in the light emitting device 300b, the LED chips may be four blue-light chips or four red-light chips so as to allow the light emitting device to provide monochromatic light. Alternatively, the LED chips may be a combination of red-light chips and blue-light chips to as to provide mixed color light. The amounts of the red-light chips and of the blue-light chips may vary according to practical needs, and the blue-light chip may use the fluorescent powder layer to provide white light. With the configuration stated above, the circuit substrate 200b and the light emitting device 300b of the present embodiment can provide plural electric loops L1 through L3. One or more LED chips may be connected thereto, and the chips may be red-light chips or blue-light chips according to practical needs, so that the light emitting device 300 emits monochromatic light or mixed color light as a combination of rays of various bands. Thereby, work circuits having the same voltage drop can be achieved using a simple combination, and this in turn allows use of a single external power source to perform control.

The present disclosure has been described with reference to the preferred embodiments and it is understood that the embodiments are not intended to limit the scope of the present disclosure. Moreover, as the contents disclosed herein should be readily understood and can be implemented by a person skilled in the art, all equivalent changes or modifications which do not depart from the concept of the present disclosure should be encompassed by the appended claims.

What is claimed is:

1. A light emitting device, comprising:
a first work circuit, comprising a first light emitting diode (LED) chip and a first bonding adhesive, wherein the first LED chip has a first forward voltage V1, and wherein the first LED chip and the first bonding adhesive are electrically connected in series; and
a second work circuit, comprising a second LED chip, wherein the second LED chip has a second forward voltage V2, and wherein a diversity ratio between the second forward voltage V2 and the first forward voltage V1 is greater than about 15%,
wherein the first work circuit has a first voltage drop V_{W1}, wherein the second work circuit has a second voltage drop V_{W2}, and wherein the first voltage drop V_{W1} is approximately equal to the second voltage drop V_{W2}.

2. The light emitting device of claim 1, further comprising:
a third work circuit, comprising a third LED chip,
wherein the third work circuit has a third voltage drop V_{W3}, and wherein the first voltage drop V_{W1} is approximately equal to the third voltage drop V_{W3}.

3. The light emitting device of claim 1, wherein the diversity ratio between the first forward voltage V1 and the second forward voltage V2 is greater than about 30%.

4. The light emitting device of claim 2, wherein the first LED chip is a red-light chip, and wherein each of the second LED chip and the third LED is a green-light chip or a blue-light chip.

5. The light emitting device of claim 1, wherein a ratio between V_{W1} and V_{W2} is about 0.785 to about 0.95.

6. The light emitting device of claim 1, wherein the first bonding adhesive comprises a resin composition that contains electrically conductive ceramic particles.

7. The light emitting device of claim 6, wherein the electrically conductive ceramic particles have a concentration of about 20% to about 80% based on weight percentage.

8. The light emitting device of claim 7, wherein the electrically conductive ceramic particles comprise indium-tin oxide particles, carbon particles, and a combination thereof.

9. The light emitting device of claim 8, wherein the resin composition comprises about 28% to about 30% of epoxy resin and about 70% to about 72% of indium-tin oxide particles based on weight percentage of the resin composition.

10. The light emitting device of claim 8, wherein the resin composition comprises about 48% to about 50% of epoxy resin and about 50% to about 52% of carbon particles based on weight percentage of the resin composition.

11. The light emitting device of claim 6, wherein the resin composition comprises metal particles.

12. The light emitting device of claim 2, wherein the first LED chip, the second LED chip and the third LED chip are electrically connected to an external power source in a common-anode or common-cathode manner.

13. The light emitting device of claim 1, wherein the first bonding adhesive has a thickness between 2 μm and 15 μm.

14. The light emitting device of claim 1, wherein the first bonding adhesive has an area between 0.015 mm² and 0.15 mm².

15. The light emitting device of claim 1, wherein the first bonding adhesive is applied through a screen printing process or a B-stage prepreg process.

16. The light emitting device of claim 1, further comprising a fluorescent powder covering the first LED chip, the second LED chip, or both the first LED chip and the second LED chip.

17. The light emitting device of claim 16, further comprising a retaining wall that is located between the first LED chip and the second LED chip.

18. The light emitting device of claim 16, wherein the retaining wall comprises a reflective material.

19. The light emitting device of claim 1, further comprising a second bonding adhesive configured to secure the second LED chip, wherein the second bonding adhesive and the second LED chip are electrically isolated.

20. The light emitting device of claim 2, further comprising a third bonding adhesive configured to secure the third LED chip, wherein the third bonding adhesive and the third LED chip are electrically isolated.
